(19) United States
(12) Patent Application Publication
(10) Pub. No.: US 2025/0142960 A1
(43) Pub. Date: May 1, 2025

(54) ARRAY SUBSTRATE, DISPLAY PANEL, AND MANUFACTURING METHOD FOR ARRAY SUBSTRATE

(71) Applicants: Fuzhou BOE Optoelectronics Technology Co., Ltd., Fuzhou, Fujian (CN); BOE Technology Group Co., Ltd., Beijing (CN)

(72) Inventors: Xin FANG, Beijing (CN); Xu XU, Beijing (CN); Xintong WU, Beijing (CN); Jie LIN, Beijing (CN); Lixia ZHANG, Beijing (CN)

(21) Appl. No.: 18/689,517

(22) PCT Filed: Feb. 23, 2023
(86) PCT No.: PCT/CN2023/077948

§ 371 Date: Mar. 6, 2024

(51) Int. Cl. H10D 86/40; G02F 1/1362; G02F 1/1368; H10D 86/60

(52) U.S. Cl. CPC H10D 86/441; G02F 1/136209; G02F 1/136286; G02F 1/1368; H10D 86/60

(57) ABSTRACT

An array substrate, including: a base; common electrode lead groups in the active area and on a side of the base, where at least one common electrode lead group includes at least one first common electrode lead extending in a first direction, and the common electrode lead groups are arranged in a second direction; and at least one common electrode connection line, which is in the non-active area, on the same side of the base as the first common electrode lead, and extends in the second direction; where a connection group is provided at a position of the common electrode connection line opposite to an end of at least one of the common electrode lead groups, the connection group includes a plurality of connectors, and the number of connectors in the connection group is not less than the number of first common electrode leads in the common electrode lead groups.

### TECHNICAL FIELD

The present disclosure relates to the technical field of semiconductors, and particularly relates to an array substrate, a display panel, and a method for manufacturing an array substrate.

### BACKGROUND

Due to the properties of low power consumption, high image quality, small size and light weight, the liquid crystal display (LCD) is very popular and has become the mainstream of current displays. A main type of current liquid crystal displays is the thin film transistor (TFT) liquid crystal display.

### SUMMARY

Embodiments of the present disclosure provide an array substrate, a display panel, and a method for manufacturing an array substrate. The array substrate has an active area and a non-active area at a periphery of the active area, wherein the array substrate includes:
a base;
a plurality of common electrode lead groups in the active area and on a side of the base, wherein at least one of the common electrode lead groups includes at least one first common electrode lead extending in a first direction, and the plurality of common electrode lead groups are arranged in a second direction; and
at least one common electrode connection line, which is in the non-active area, on the same side of the base as the first common electrode lead, and extends in the second direction;
wherein a connection group is provided at a position of the common electrode connection line opposite to an end of at least one of the common electrode lead groups, the connection group includes a plurality of connectors, and the number of connectors in the connection group is not less than the number of first common electrode leads in the common electrode lead groups.

In a possible implementation, the common electrode lead groups include only one first common electrode lead; and
the connection group includes two connectors, one of which is electrically connected to the first common electrode lead.

In a possible implementation, the common electrode lead groups include two first common electrode leads; and
the connection group includes two connectors, one of which is electrically connected to one of the first common electrode leads opposite thereto, and the other of which is electrically connected to the other first common electrode lead.

In a possible implementation, the common electrode connection line includes a body part between two adjacent common electrode lead groups, and a connection part connecting adjacent body parts; wherein a width of the connection part in the first direction is less than a width of the body part in the first direction; and
the two connectors respectively extend in the second direction from an adjacent body part, a gap is provided between the two connectors in the second direction, and the body part, the connection part, and the two connectors form a hollowed-out region opening toward the first common electrode lead.

In a possible implementation, the hollowed-out region has a symmetry axis parallel to the first direction, and the two connectors are symmetrical about the symmetry axis.

In a possible implementation, the array substrate further includes a gate line layer, and a pixel electrode layer on a side of the gate line layer facing away from the base;
the gate line layer includes: a plurality of gate lines extending in the first direction, the first common electrode lead, and the common electrode connection line; and
the pixel electrode layer includes a plurality of pixel electrodes, an orthographic projection of a portion of each pixel electrode facing a corresponding gate line on the base has an overlap region with an orthographic projection of the first common electrode lead on the base.

In a possible implementation, the array substrate further includes a data line layer;
the array substrate further includes a gate driver circuit in the non-active area, and gate output signal leads led out from the gate driver circuit and extending in the first direction, wherein the gate output signal leads are in the data line layer; and
the gate output signal leads are conducted with the gate lines in the hollowed-out region through transfer structures.

In a possible implementation, two gate lines are provided between adjacent pixel electrode rows, and two transfer structures corresponding to the two gate lines are symmetrical about the symmetry axis.

In a possible implementation, between an area where the gate driver circuit is located and an area where the common electrode connection line is located, the array substrate is further provided with first output signal wiring areas and second output signal wiring areas; in the second direction, at least part of the first output signal wiring areas and at least part of the second output signal wiring areas are alternately arranged;
each gate output signal lead includes a first output signal wiring part extending in the first direction, and a second output signal wiring part extending in the second direction; the second output signal wiring part is in a corresponding first output signal wiring area;
each second output signal wiring area is further provided with a plurality of first floating leads extending in the second direction and arranged in the first direction.

In a possible implementation, each first output signal wiring area is further provided with a second floating lead extending in the second direction.

In a possible implementation, the number of first floating leads in the second output signal wiring area is equal to a sum of the number of second output signal wiring parts and the number of second floating leads in the first output signal wiring area;
a width of each first floating lead in the first direction is substantially the same as a width of the second output signal wiring part in the second direction; a width of the second floating lead in the first direction is substantially the same as a width of the second output signal wiring part in the first direction;
in the first output signal wiring area, a line spacing between the second output signal wiring part and the adjacent second floating lead is substantially equal, and a line spacing between adjacent second output signal wiring parts is substantially equal; and in the second output signal wiring area, a line spacing between adjacent first floating leads is substantially equal.

In a possible implementation, the data line layer further includes: a plurality of data lines extending in the second direction, a transistor first electrode electrically connected to a corresponding data line, a transistor second electrode spaced apart from the transistor first electrode, and a plurality of second common electrode leads extending in the second direction, wherein the data lines and the second common electrode leads are alternately arranged in the first direction;
the plurality of pixel electrodes include a first type pixel electrode and a second type pixel electrode alternately arranged in the first direction;
the first type pixel electrode includes: a first main part, a first transfer part, and a first connection part connecting the first main part and the first transfer part; an orthographic projection of the first transfer part on the base has an overlap region with an orthographic projection of the transistor second electrode on the base;
the second type pixel electrode includes: a second main part, and a second transfer part directly connected to the second main part, wherein an orthographic projection of the second transfer part on the base has an overlap region with an orthographic projection of the transistor second electrode on the base;
the second type pixel electrode further includes: a compensation part extending from the second transfer part in the first direction away from the corresponding data line, wherein an orthographic projection of the compensation part on the base is overlapped with an orthographic projection of a corresponding second common electrode lead on the base.

In a possible implementation, an overlap area formed by the orthographic projection of the compensation part on the base and the orthographic projection of the corresponding second common electrode lead on the base, is substantially the same as an overlap area formed by the orthographic projection of the first connection part on the base and the orthographic projection of the second common electrode lead on the base.

In a possible implementation, the non-active area further includes a common electrode auxiliary connection line on a side of the common electrode connection line away from the active area; and
the common electrode auxiliary connection line is electrically conducted with the common electrode connection line.

In a possible implementation, the non-active area is further provided with a plurality of fan-shaped wiring areas, and a common signal input area is further arranged between adjacent fan-shaped wiring areas;
the fan-shaped wiring area includes: a first fan-shaped wiring subarea and a second fan-shaped wiring subarea, wherein the first fan-shaped wiring subarea is provided with a plurality of first fan-shaped area wires extending in a third direction, and the second fan-shaped wiring subarea is provided with a plurality of second fan-shaped area wires extending in a fourth direction; and
the common signal input area includes: a first common signal input subarea and a second common signal input subarea, wherein the first common signal input subarea is adjacent to the second fan-shaped wiring subarea in one of the fan-shaped wiring areas, and the second common signal input subarea is adjacent to the first fan-shaped wiring subarea in another one of the fan-shaped wiring areas; and
the first common signal input subarea is provided with a plurality of first auxiliary wires extending in the fourth direction, and the second common signal input subarea is provided with a plurality of second auxiliary wires extending in the third direction.

In a possible implementation, the fan-shaped wiring area includes first fan-shaped area wires having substantially the same line width, and second fan-shaped area wires having substantially the same line width, and at least part of the first fan-shaped area wires have substantially the same line width as at least part of the second fan-shaped area wires; and
at least part of the first auxiliary wires have substantially the same line width, at least part of the second auxiliary wires have substantially the same line width, and at least part of the first auxiliary wires have substantially the same line width as at least part of the second auxiliary wires and as the at least part of the first fan-shaped area wires.

In a possible implementation, for the first fan-shaped area wires and the second fan-shaped area wires in the fan-shaped wiring area, at least part of the wires have different line widths; and
all the first auxiliary wires have substantially the same line width, and all the second auxiliary wires have substantially the same line width, the first auxiliary wires and the second auxiliary wires have substantially the same line width, satisfying Wf1≤Wc1≤Wf2, where Wc1 represents a line width of any first auxiliary wire, Wf1 represents a minimum line width value in the fan-shaped wiring area, and Wf2 represents a maximum line width value in the fan-shaped wiring area.

In a possible implementation, for the first fan-shaped area wires and the second fan-shaped area wires in the fan-shaped wiring area, at least part of the wires have different line widths; and
at least part of the first auxiliary wires have different line widths, satisfying Wf1≤Wc1≤Wf2, where Wc1 represents a line width of any first auxiliary wire, Wf1 represents a minimum line width value in the fan-shaped wiring area, and Wf2 represents a maximum line width value in the fan-shaped wiring area; and
at least part of the second auxiliary wires have different line widths, satisfying Wf1≤Wc2≤Wf2, where Wc2 represents a line width of any second auxiliary wire, Wf1 represents a minimum line width value in the fan-shaped wiring area, and Wf2 represents a maximum line width value in the fan-shaped wiring area.

In a possible implementation, in the fan-shaped wiring area, adjacent first fan-shaped area wires have substantially the same line spacing therebetween, and adjacent second fan-shaped area wires have substantially the same line spacing therebetween;
adjacent first auxiliary wires have substantially the same line spacing, which is substantially the same as the line spacing between the adjacent second fan-shaped area wires; and adjacent second auxiliary wires have substantially the same line spacing, which is substantially the same as the line spacing between the adjacent first fan-shaped area wires.

In a possible implementation, a minimum distance between the first auxiliary wires and the second fan-shaped area wires is substantially the same as the line spacing between the adjacent second fan-shaped area wires; and
a minimum distance between the second auxiliary wires and the first fan-shaped area wires is substantially the same as the line spacing between the adjacent first fan-shaped area wires.

In a possible implementation, the common signal input area is further provided with at least one third auxiliary wire extending in the first direction, and the first auxiliary wires and the second auxiliary wires are both intersected with and electrically connected to the third auxiliary wire.

In a possible implementation, the common signal input area is further provided with at least one fourth auxiliary wire extending in the second direction, and the first auxiliary wires, the second auxiliary wires and the third auxiliary wire are all intersect with and electrically connected to the fourth auxiliary wire;
the first common signal input subarea is further provided with at least one fifth auxiliary wire extending in the second direction, and the first auxiliary wires and the third auxiliary wire are both intersected with and electrically connected to the fifth auxiliary wire; and
the second common signal input subarea is further provided with at least one sixth auxiliary wire extending in the second direction, and the second auxiliary wires and the third auxiliary wire are both intersected with and electrically connected to the sixth auxiliary wire.

In a possible implementation, the first fan-shaped area wires and the second fan-shaped area wires are in the same layer; and
the first auxiliary wires and the second auxiliary wires are in the same layer, and in the same layer as the first fan-shaped area wires.

In a possible implementation, adjacent first fan-shaped area wires are in different layers, different layers of first fan-shaped area wires are alternately arranged, adjacent second fan-shaped area wires are in different layers, and different layers of second fan-shaped area wires are alternately arranged;
adjacent first auxiliary wires are in different layers, and different layers of first auxiliary wires are alternately arranged; and adjacent second auxiliary wires are in different layers, and different layers of second auxiliary wires are alternately arranged.

In a possible implementation, one of the first auxiliary wires and one of the second fan-shaped area wires closest to each other are in different layers; and
one of the second auxiliary wires and one of the first fan-shaped area wires closest to each other are in different layers.

In a possible implementation, at least one of the third auxiliary wire, the fourth auxiliary wire, the fifth auxiliary wire, or the sixth auxiliary wire includes a plurality of metal layers arranged in a stack.

An embodiment of the present disclosure further provides a display panel, including the array substrate provided in any embodiment of the present disclosure, and an opposite substrate opposite to the array substrate.

In a possible implementation, two gate lines, a first gate line and a second gate line, are provided between adjacent pixel electrode rows;
the opposite substrate further includes a first spacer and a second spacer on a side of a black matrix layer facing the array substrate, wherein a height of the first spacer in a direction perpendicular to the base is greater than a height of the second spacer in the direction perpendicular to the base; an orthographic projection of the first gate line on the base covers an orthographic projection of the second spacer on the base, and an orthographic projection of the second gate line on the base covers an orthographic projection of the first spacer on the base; and
in an area where at least part of data lines are located, the first spacer and the second spacer are respectively on different sides of the data line, and for the first spacers and the second spacers on different sides of the same data line, the number of the first spacers is less than the number of the second spacers.

In a possible implementation, the opposite substrate has the black matrix layer having a plurality of pixel openings, and a minimum distance al between the second gate line and an adjacent pixel opening satisfies:
a1=a2+a3+a4, where a2 represents a minimum distance from a first common electrode lead on a side of the first gate line away from the second gate line, to a closest pixel opening, a2 represents a maximum line width of the first common electrode lead on the side of the first gate line away from the second gate line, and a3 represents a minimum distance from the first common electrode lead on the side of the first gate line away from the second gate line, to a closest first gate line.

An embodiment of the present disclosure further provides a method for manufacturing the array substrate according to any embodiment of the present disclosure, including:
forming, by a first mask, a plurality of common electrode lead groups and at least one common electrode connection line on a side of a base of an array substrate to be detected, wherein at least one of the common electrode lead groups includes one first common electrode lead extending in a first direction, and a connection group is provided at a position of the common electrode connection line opposite to an end of the first common electrode lead, and the connection group includes a plurality of connectors, one of which is electrically connected to the opposite first common electrode lead; and
when determining that a delay of a common electrode signal of the array substrate exceeds a first time length, replacing the first mask with a second mask, and, for the array substrate, subsequently forming a plurality of common electrode lead groups and at least one common electrode connection line on a side of the base by the second mask, wherein at least one of the common electrode lead groups includes a plurality of first common electrode leads extending in a first direction, and a connection group is provided at a position of the common electrode connection line opposite to an end of the first common electrode lead, and the connection group includes a plurality of connectors in one-to-one correspondence and electrical connection with the first common electrode leads.

In a possible implementation, the method further includes:
when determining that the delay of the common electrode signal of the array substrate is less than the first time length, for the array substrate, subsequently forming a plurality of common electrode lead groups and at least one common electrode connection line on a side of the base by the first mask.

### BRIEF DESCRIPTION OF DRAWINGS

FIG. 1 is a schematic diagram of signal wiring at a periphery of a display panel;

FIG. 2 is a first schematic diagram of an array substrate according to an embodiment of the present disclosure;

FIG. 3A is an enlarged view at dashed box A in FIG. 2;

FIG. 3B is a schematic diagram showing a single film layer of a first common electrode lead in FIG. 3A;

FIG. 4 is a second schematic diagram of an array substrate according to an embodiment of the present disclosure;

FIG. 5A is an enlarged view at dashed box A in FIG. 4;

FIG. 5B is a schematic diagram showing a single film layer of a first common electrode lead in FIG. 5A;

FIG. 6A is an enlarged view at dashed box C in FIG. 2;

FIG. 6B is a schematic diagram showing a single film layer of only a gate line layer in FIG. 6A;

FIG. 6C is a schematic diagram showing the film layer in FIG. 6B superimposed with a data line;

FIG. 6D is a schematic sectional view taken along dashed line 001 in FIG. 6A;

FIG. 7 is an enlarged view at dashed box D in FIG. 2;

FIG. 8A is a third schematic diagram of an array substrate according to an embodiment of the present disclosure;

FIG. 8B may be an enlarged view at dashed box E in FIG. 8A;

FIG. 8C may be an enlarged view at dashed box F in FIG. 8A;

FIG. 8D may be an equivalent circuit diagram corresponding to FIG. 8A;

FIG. 8E is a schematic diagram showing a single film layer of a common electrode layer in FIG. 8A;

FIG. 8F is a schematic diagram showing a single film layer of a gate line layer in FIG. 8A;

FIG. 8G is a schematic diagram showing a single film layer of a data line layer in FIG. 8A;

FIG. 8H may be a schematic sectional view taken along dashed line OO′ in FIG. 8B;

FIG. 9A is a fourth schematic diagram of an array substrate according to an embodiment of the present disclosure;

FIG. 9B is an enlarged view of one first spacer PS1 disposed within dashed box G in FIG. 9A;

FIG. 9C is an enlarged view of two second spacers PS2 disposed within dashed box G in FIG. 9A;

FIG. 10A is a fifth schematic diagram of an array substrate according to an embodiment of the present disclosure;

FIG. 10B is a sixth schematic diagram of an array substrate according to an embodiment of the present disclosure;

FIG. 11 is a first schematic diagram of a plurality of fan-shaped wiring areas according to an embodiment of the present disclosure;

FIG. 12A is a second schematic diagram of a plurality of fan-shaped wiring areas according to an embodiment of the present disclosure;

FIG. 12B is a second schematic diagram of a plurality of fan-shaped wiring areas according to an embodiment of the present disclosure;

FIG. 13A may be an enlarged view at dashed box H1 in FIG. 12A;

FIG. 13B may be an enlarged view at dashed box H2 in FIG. 12A;

FIG. 13C may be an enlarged view at dashed box H3 in FIG. 12A;

FIG. 13D may be an enlarged view at dashed box H4 in FIG. 12A;

FIG. 14 is a first schematic flowchart of a process for manufacturing an array substrate according to an embodiment of the present disclosure; and

FIG. 15 is a second schematic flowchart of a process for manufacturing an array substrate according to an embodiment of the present disclosure.

### DETAIL DESCRIPTION OF EMBODIMENTS

To make the objects, technical solutions and advantages of the embodiments of the present disclosure more apparent, the technical solutions according to the embodiments of the present disclosure will be clearly and completely described below with reference to the drawings of the embodiments of the present disclosure. Apparently, the described embodiments are some, but not all, of the embodiments of the present disclosure. All other embodiments obtained by those skilled in the art based on the embodiments of the present disclosure described herein without paying any creative effort shall be included in the protection scope of the present disclosure.

Unless otherwise defined, technical or scientific terms used in the present disclosure are intended to have general meanings as understood by those skilled in the art to which the present disclosure belongs. The words “first”, “second” and similar terms used in the present disclosure do not denote any order, quantity, or importance, but are used merely for distinguishing different components from each other. The word “comprise” or “include” or the like means that the element or item preceding the word contains elements or items that appear after the word or equivalents thereof, but does not exclude other elements or items. The terms “connected” or “coupled” and the like are not restricted to physical or mechanical connections, but may include electrical connections, whether direct or indirect. The words “upper”, “lower”, “left”, “right”, and the like are merely used to indicate a relative positional relationship, and when an absolute position of the described object is changed, the relative positional relationship may be changed accordingly.

The words “about” or “substantially the same” as used herein includes the stated value and means within an acceptable range of deviation for the particular value as determined by those skilled in the art in view of the measurement in question and the errors associated with the measurement of the particular quantity (i.e., limitations of the measurement system). For example, “substantially the same” may mean a difference relative to the stated value within one or more standard deviations, or within ±30%, ±20%, ±10%, or ±5%.

In the drawings, layers, films, panels, areas, and the like are shown with enlarged thicknesses for clarity. Exemplary implementations are described herein with reference to cross-sectional views that are taken as schematic diagrams of ideal implementations. As such, deviations from the shapes in the figures as a result of, for example, manufacturing techniques and/or tolerances, are to be expected. Thus, implementations described herein should not be construed as limited to the particular shapes of areas as illustrated herein, but are to include deviations in shapes that result from, for example, manufacturing. For example, areas illustrated or described as flat may typically have rough and/or nonlinear features. Further, the illustrated sharp corners may be rounded. Therefore, the areas illustrated in the figures are schematic in nature and their shapes are not intended to illustrate the precise shapes of the areas, and are not intended to limit the scope of the present claims.

In the pixel design of an active area of the LCD panel, the common signal electrode (Com) is designed as a full-surface matrix. The common electrode lead (Com signal line) that provides a signal for the common electrode typically has a high resistance, which may easily lead to Image Sticking (I/S), greenish defects, or other poor display problems. However, if a density of the metal Com signal lines is increased to reduce the resistance of the Com signal lines in a screen, the loads on the data line (Data) and/or the gate line (Gate) may be increased, causing the risk of insufficient charging rate due to signal delay caused by the increased loads on the signal lines.

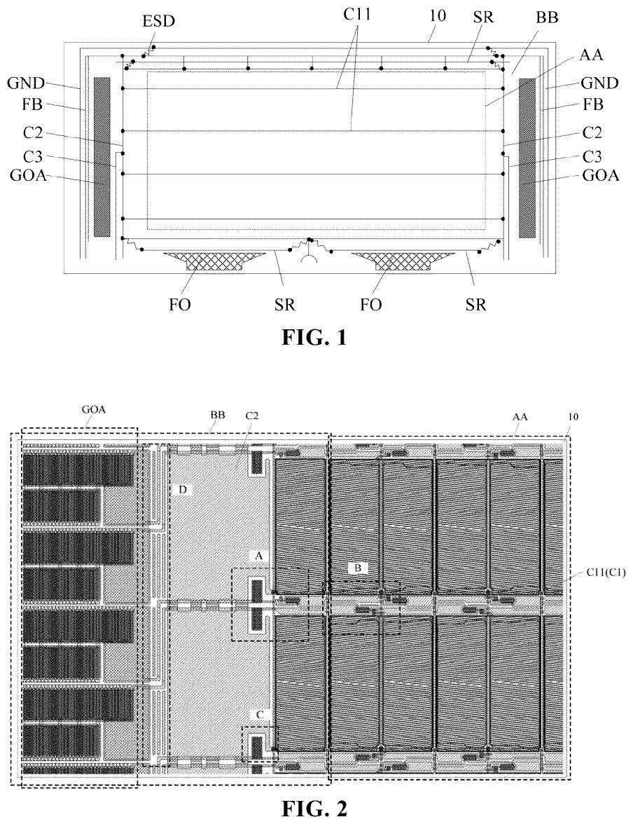

In the design of an LCD panel, as shown in FIG. 1, a periphery of an active area AA may be provided with a gate driver on array GOA, a feedback signal line FB (for monitoring a Com signal at a far end, i.e., a side away from a bonding area of the flexible circuit board, and when a fluctuation of the Com signal is monitored, the Com signal is designed to be compensated. For example, a greater fluctuation value of the Com signal needs a smaller compensation value, and a smaller fluctuation value needs a larger compensation value, which means that complementary compensation principle is adopted to achieve stable and uniform output of the common signal), a ground line GND, a short ring SR, and a Com metal (e.g., a common electrode connection line C2 and/or a common electrode auxiliary connection line C3). The Com signal is input to the screen through a transverse Com metal line (e.g., a first common electrode lead C11). Generally, only one Com metal line is designed in each pixel. However, on the one hand, for some large-sized, low-resolution display panels with high refresh rate specifications, the design of only one Com metal line per pixel may cause an excessive Com signal resistance in the screen, leading to severe signal delay and poor display risks related to an insufficient Com signal driving capability. On the other hand, if the phenomenon of the excessive Com signal resistance and severe signal delay does not occur in the screen, more than one (e.g., two) Com metal lines for each pixel may increase the capacitive load of the pixel drive signals (e.g., Gate and Data signal lines), resulting in an insufficient pixel charging rate and other problems.

To keep the following description of the embodiments of the present disclosure clear and concise, detailed description of known functions and known components is omitted herein.

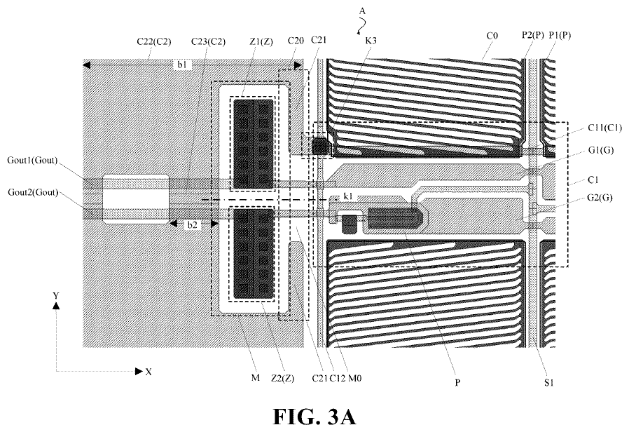

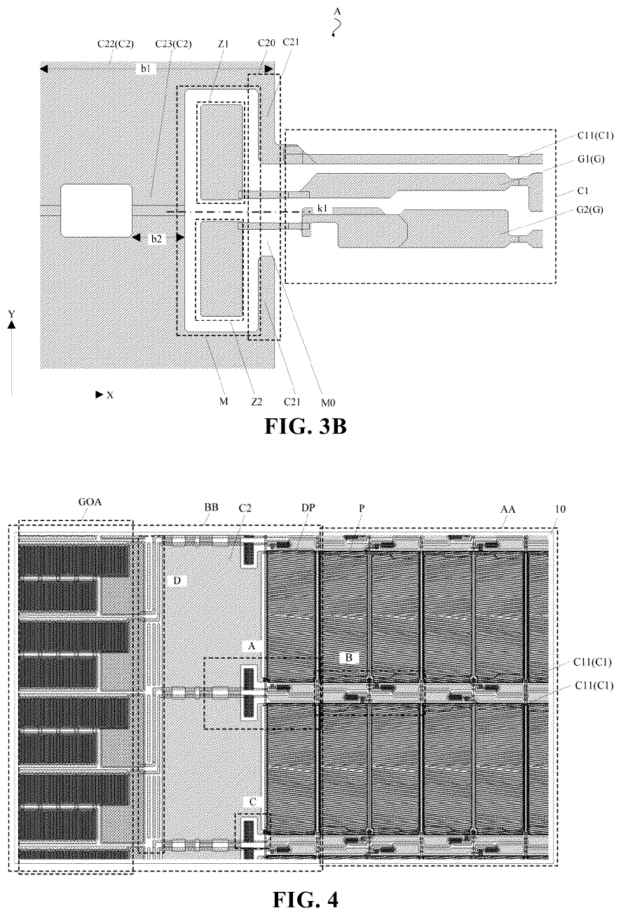

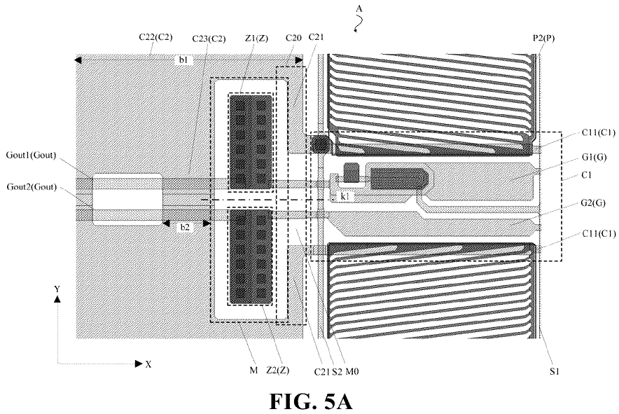

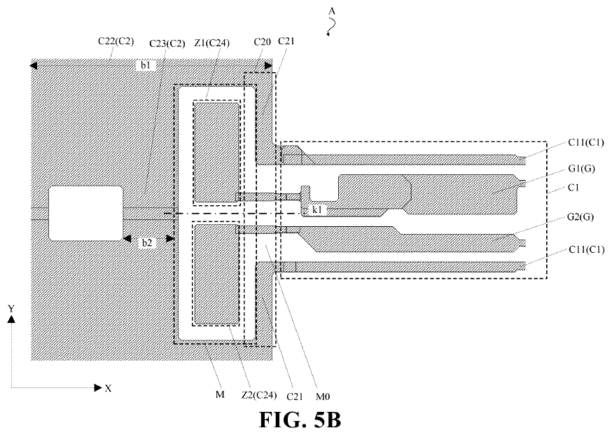

An embodiment of the present disclosure provides an array substrate as shown in FIGS. 2 to 5B, where FIG. 3A is an enlarged view at dashed box A in FIG. 2, FIG. 3B is a schematic diagram showing a single film layer of a first common electrode lead in FIG. 3A, FIG. 5A is an enlarged view at dashed box A in FIG. 4, and FIG. 5B is a schematic diagram showing a single film layer of a first common electrode lead in FIG. 5A. The array substrate has an active area AA, and a non-active area BB at a periphery of the active area AA. The array substrate includes:
a base 10;
a plurality of common electrode lead groups C1 in the active area AA and on a side of the base 10. At least one of the electrode lead groups C1 includes at least one first common electrode lead C11 extending in a first direction X, and the plurality of common electrode lead groups C1 are arranged in a second direction Y. Specifically, the second direction Y may be intersected with the first direction X, and more specifically, the second direction Y may be perpendicular to the first direction X.

The array substrate further includes: at least one common electrode connection line C2, which is in the non-active area BB, located on the same side of the base 10 as the first common electrode lead C11, and extends in the second direction Y.

A connection group C20 is provided at a position of the common electrode connection line C2 opposite to an end of at least one of the common electrode lead groups C1. The connection group C20 includes a plurality of connectors C21, and the number of connectors C21 in the connection group C20 is not less than the number of first common electrode leads C11 in the common electrode lead groups C1. Specifically, at least a part of the connectors C21 in the connection group C20 are electrically connected to opposite first common electrode leads C11, or all the connectors C21 in the connection group C20 are electrically connected, in one-to-one correspondence, to opposite first common electrode leads C11.

In an embodiment of the present disclosure, within the connection group C20, it is possible that all of the connectors C21 are electrically connected, in one-to-one correspondence, to the opposite first common electrode leads C11, or part of the connectors C21 in the connection group C20 are electrically connected to the opposite first common electrode leads C11. In other words, redundant connectors C21 may be reserved in the connection group C20, and in the manufacturing process of the array substrate, for example, before manufacturing the display panel, a film layer of the first common electrode lead C11 may be firstly manufactured by a first mask, where the first mask has a mask pattern of the common electrode lead group C1 including one first common electrode lead C11, and the first common electrode lead C11 is electrically connected to one of the connectors C21. If it is found that the manufactured display panel may have an excessively large Com signal resistance, severe signal delay, or poor display problems related to an insufficient Com signal driving capability, the first mask may be changed and replaced with a second mask, where the second mask has a mask pattern of the common electrode lead group C1 including two first common electrode leads C11, and the two first common electrode leads C11 are electrically connected to the opposite connectors C21, respectively. In this manner, by changing one mask, for example, the one first common electrode lead C11 design is changed into the two first common electrode leads C11 design, the Com signal resistance is reduced, and the problem of poor display caused by the excessive Com signal resistance in the display panel is solved with the minimum cost.

Specifically, when the film layer of the first common electrode lead C11 is manufactured by the first mask, if it is found that the manufactured display panel does not have an excessively large Com signal resistance, severe signal delay, or poor display problems related to an insufficient Com signal driving capability, the first mask does not need to be changed during manufacturing of the panel. That is, the film layer of the first common electrode lead C11 is manufactured by the first mask. The array substrate provided in the embodiments of the present disclosure can support two wiring modes of Com signals, and support diversity of the display panel while reducing the cost.

Specifically, referring to FIGS. 2 to 3B, the common electrode lead groups C1 include only one first common electrode lead C11; and the connection group C20 includes two connectors C21, one of which is electrically connected to the first common electrode lead C11. The remaining connector C21 may be in a state out of connection with any first common electrode lead C21. Specifically, referring to FIG. 3B, for example, in FIG. 3B, an upper connector C21 in the connection group C20 is electrically connected to an upper first common electrode lead C11 in the common electrode lead group C1, while a lower connector C21 in the connection group C20 is in an unconnected state.

Specifically, referring to FIGS. 4 to 5B, the common electrode lead groups C1 include two first common electrode leads C11; and the connection group C20 includes two connectors C21, one of which is electrically connected to one of the first common electrode leads C11 opposite thereto, and the other of which is electrically connected to the other first common electrode lead C21. Specifically, referring to FIG. 5B, for example, in FIG. 5B, an upper connector C21 in the connection group C20 is electrically connected to an upper first common electrode lead C11 in the common electrode lead group C1, while a lower connector C21 in the connection group C20 is electrically connected to a lower first common electrode lead C11 in the common electrode lead group C1.

In a possible implementation, an embodiment of the present disclosure provides a specific design structure of two connectors C21. Referring to FIGS. 2 to 5B, the common electrode connection line C2 includes a body part C22 between two adjacent common electrode lead groups C1, and a connection part C23 connecting adjacent body parts C22. A width b2 of the connection part C23 in the first direction X is less than a width b1 of the body part C22 in the first direction X. The two connectors C21 respectively extend in the second direction Y from an adjacent body part C22, a gap MO is provided between the two connectors C21 in the second direction Y, and the body part C22, the connection part C23, and the two connectors C21 form a hollowed-out region M opening toward the first common electrode lead C11. The hollowed-out region M may reserve a space for subsequent transfer of a gate output signal lead Gout and a gate line G, and the two connectors C21 are located on two sides of the opening of the hollowed-out region M, to prevent overlapping with a projection of the gate line G, and further avoiding a capacitive load on the gate line G.

Specifically, referring to FIGS. 2 to 5B, the hollowed-out region M has a symmetry axis k1 parallel to the first direction X, and the two connectors C21 are symmetrical about the symmetry axis k1. With the hollowed-out region M symmetrical about the symmetry axis k1, two transfer structures Z1 (structures for transfer and conduction of the two gate output signal leads Gout and the two gate lines G, respectively) can be conveniently arranged. In other words, two transfer structures Z may be arranged on upper and lower sides of the symmetry axis k1 in the hollowed-out region M, respectively, thereby achieving regular space arrangement, saving the wiring space, and reducing the risk of poor wiring.

Specifically, the two connectors C21 symmetrical about the symmetry axis k1 may be interpreted as that the two connectors C21 have the same shape, substantially the same distance from the symmetry axis k1, substantially the same extension length in the second direction Y, and substantially the same width in the first direction X. It will be understood that “substantially the same” may refer to two items the same within a permissible range of the process tolerance, for example, within 1 μm of the process tolerance.

In a possible implementation, referring to FIGS. 2 to 5B, the array substrate further includes a gate line layer, and a pixel electrode layer on a side of the gate line layer facing away from the base. The gate line layer includes: a plurality of gate lines G extending in the first direction X, the first common electrode lead C11, and the common electrode connection line C2. In other words, the first common electrode lead C11 and the common electrode connection line C2 may be disposed in the same layer as the gate lines G. The pixel electrode layer includes a plurality of pixel electrodes P, and an orthographic projection of a portion of each pixel electrode P facing a corresponding gate line G on the base 10 has an overlap region with an orthographic projection of the first common electrode lead C11 on the base 10.

Specifically, two gate lines G, a first gate line G1 and a second gate line G2, are provided between adjacent pixel electrode rows, and one first common electrode lead C11 may be located on a side of the first gate line G1 away from the second gate line G2, for example, as shown in FIG. 3A, on an upper side of the first gate line G1. If the common electrode lead group C1 includes two first common electrode leads C11, the other first common electrode lead C11 may be located on a side of the second gate line G2 away from the first gate line G1, for example, as shown in FIG. 5A, on a lower side of the second gate line G2.

In a possible implementation, referring to FIGS. 2 to 5B, the array substrate further includes a data line layer between the gate line layer and the pixel electrode layer. The array substrate further includes a gate driver circuit GOA in the non-active area BB, and gate output signal leads Gout led out from the gate driver circuit GOA and extending in the first direction X. The gate output signal leads Gout are located in the data line layer. The gate output signal leads Gout are conducted with the gate lines G in the hollowed-out region M through transfer structures Z.

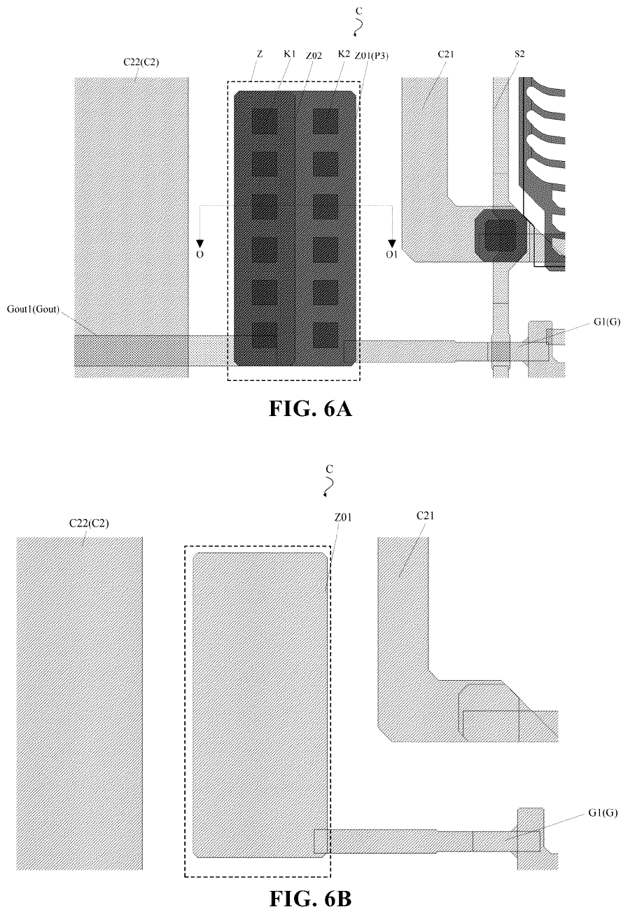

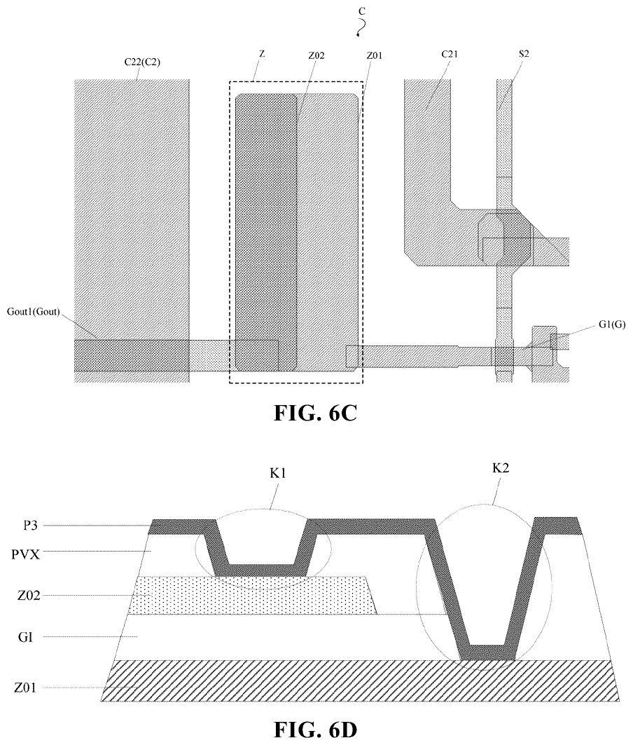

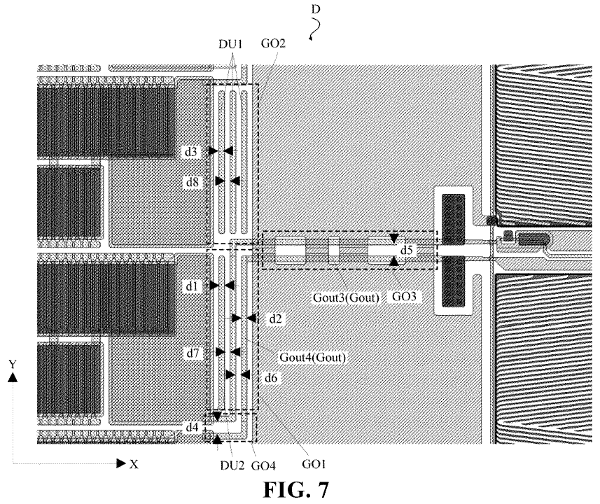

In a possible implementation, referring to FIGS. 6A to 6D, where FIG. 6B is a schematic diagram showing a single film layer of only a gate line layer in FIG. 6A, FIG. 6C is a schematic diagram showing the film layer in FIG. 6B superimposed with a data line, and FIG. 6D is a schematic sectional view taken along dashed line 001 in FIG. 6A, each transfer structure Z may include a first transfer part Z01, a gate insulation layer GI, a second transfer part Z02, a passivation layer PVX, and a third transfer part P3, which are sequentially positioned on a side of the base 10. The first transfer part Z01 may be disposed in the same layer as the gate line G and electrically connected to an end of the gate line G facing the gate driver circuit GOA, the second transfer part Z02 may be located in the data line layer, and electrically connected to an end of the gate output signal lead Gout facing the gate line G, and the third transfer part Z03 may be located in the pixel electrode layer. The first transfer part Z01 is conducted with the third transfer part P3 through a second via K2, and the second transfer part Z02 is conducted with the third transfer part P3 through a first via K1, thereby conducting the first transfer part Z01 and the second transfer part Z02, and further the gate output signal lead Gout and the gate line G.

In a possible implementation, referring to FIGS. 2 to 5B, two transfer structures Z corresponding to the two gate lines G are symmetrical about the symmetry axis k1. Specifically, the two transfer structures Z symmetrical about the symmetry axis k1 may be interpreted as that corresponding film layers in the two transfer structures Z are symmetrical about the symmetry axis k1. For example, the two transfer structures Z are a first transfer structure Z1 and a second transfer structure Z2, where a first transfer part Z01 in the first transfer structure Z1 is symmetrical about the symmetry axis k1 with a first transfer part Z01 in the second transfer structure Z2; a second transfer part Z02 in the first transfer structure Z1 is symmetrical about the symmetry axis k1 with a second transfer part Z02 in the second transfer structure Z2; a third transfer part P3 in the first transfer structure Z1 is symmetrical about the symmetry axis k1 with a third transfer part P3 in the second transfer structure Z2; a first via K1 in the first transfer structure Z1 is symmetrical about the symmetry axis k1 with a first via K1 in the second transfer structure Z2; and a second via K2 in the first transfer structure Z1 is symmetrical about the symmetry axis k1 with a second via K2 in the second transfer structure Z2.

Specifically, as shown in FIGS. 6A to 6D, within the same transfer structure Z, a plurality of first vias K1 and a plurality of second vias K2 are provided.

In a possible implementation, referring to FIG. 7, FIG. 7 may be an enlarged view around dashed box D in FIG. 2, where between an area where the gate driver circuit GOA is located and an area where the common electrode connection line C2 is located, the array substrate is further provided with first output signal wiring areas GO1 and second output signal wiring areas GO2. In the second direction Y, at least part of the first output signal wiring areas GO1 and at least part of the second output signal wiring areas GO2 are alternately arranged. Each gate output signal lead Gout includes a first output signal wiring part Gout3 extending in the first direction X, and a second output signal wiring part Gout4 extending in the second direction Y. The second output signal wiring part Gout4 is located in a corresponding first output signal wiring area GO1. Each second output signal wiring area GO2 is further provided with a plurality of first floating leads DU1 extending in the second direction Y and arranged in the first direction X.

In specific implementations, when serial numbers of the gate lines G in the pixel and serial numbers of the GOA units in the gate driver circuit GOA in the active area AA are out of order in the spatial arrangement, for example, when an (n−1)^{th} GOA unit is directly aligned with an n^{th} gate line G in the first direction X, and an n^{th} GOA unit is directly aligned with an (n+1)^{th} gate line G in the first direction X, which means that the serial number of the GOA unit is different from the serial number of the gate line G by 1, the gate output signal leads Gout have to be wired by turning, resulting in a first output signal wiring area GO1, a second output signal wiring area GO2, a third output signal wiring area GO3, and a fourth output signal wiring area GO4, where the second output signal wiring area GO2 has no gate output signal lead Gout. In an embodiment of the present disclosure, the second output signal wiring area GO2 is further provided with a plurality of first floating leads DUI extending in the second direction Y and arranged in the first direction X, so that when a data line layer is manufactured, the metal etching solution has a uniform concentration, which is beneficial to obtaining gate output signal leads Gout with a uniform line width.

In a possible implementation, referring to FIG. 7, the first output signal wiring area GO1 is further provided with a second floating lead DU2 extending in the second direction Y. In this manner, the first output signal wiring area GO1 has a uniform wiring arrangement, which is beneficial to a uniformly distributed concentration of the metal etching solution, and thus reduces the probability of non-uniform line widths of the gate output signal leads Gout.

In a possible implementation, referring to FIG. 7, the number of first floating leads DU1 in the second output signal wiring area GO2 is equal to a sum of the number of second output signal wiring parts Gout4 and the number of second floating leads DU2 in the first output signal wiring area GO1. For example, in FIG. 7, a sum of the number of second output signal wiring parts Gout4 and the number of second floating leads DU2 in the first output signal wiring area GO1 is 3, and the number of first floating leads DU1 in the second output signal wiring area GO2 is also 3. A width d3 of each first floating lead DU1 in the first direction X is substantially the same as a width d2 of the second output signal wiring part Gout4 in the first direction X. A width d1 of each second floating lead DU2 in the first direction X is substantially the same as a width d2 of the second output signal wiring part Gout4 in the first direction X. In the first output signal wiring area GO1, a line spacing d7 between the second output signal wiring part Gout4 and the adjacent second floating lead DU2 is substantially equal, and a line spacing d6 between adjacent second output signal wiring parts Gout4 is substantially equal. In the second output signal wiring area GO2, a line spacing d8 between adjacent first floating leads DUI may be substantially equal.

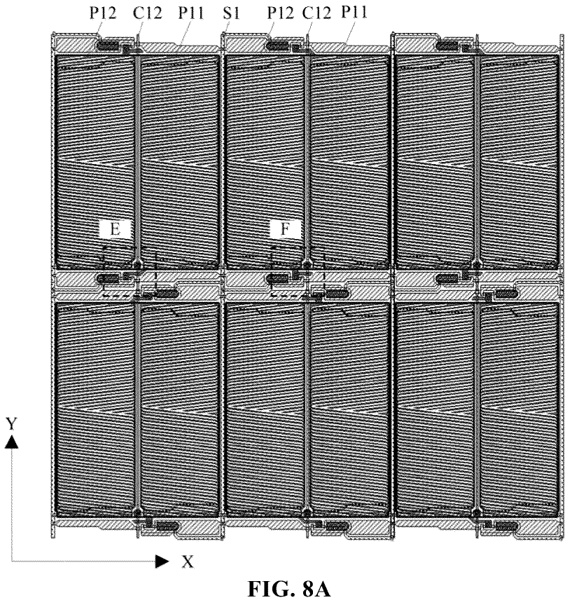

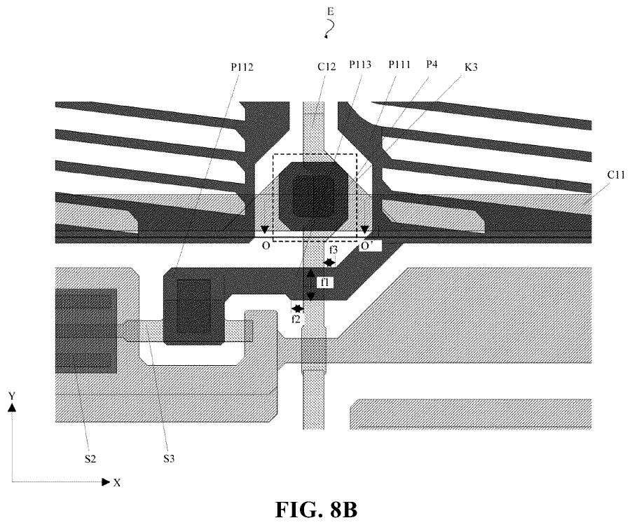

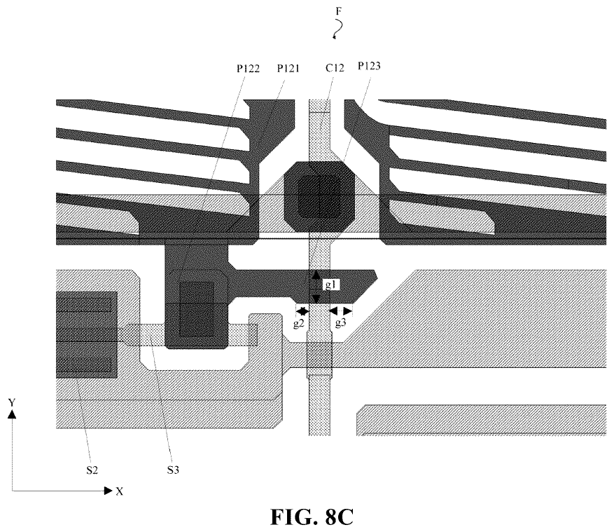

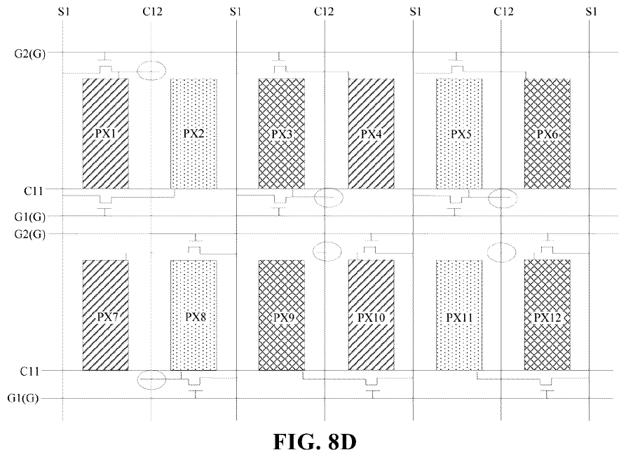

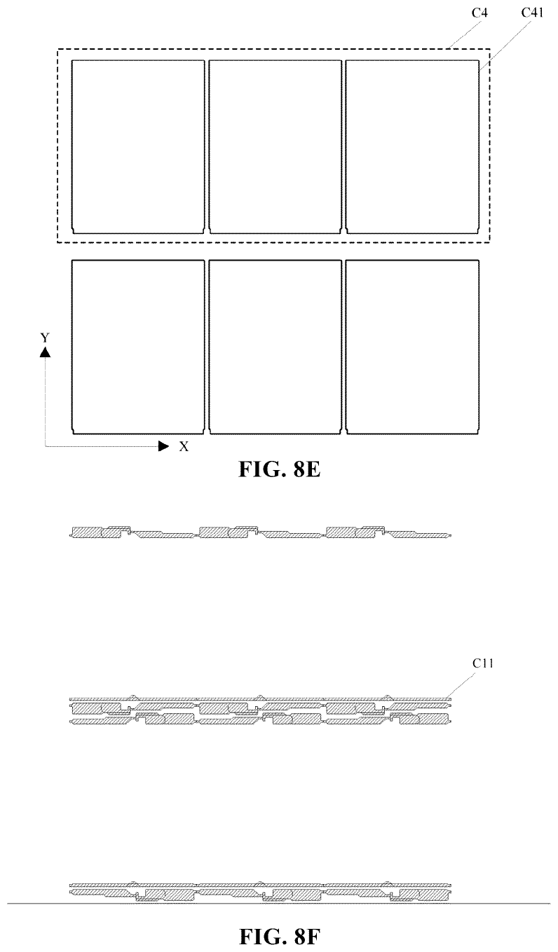

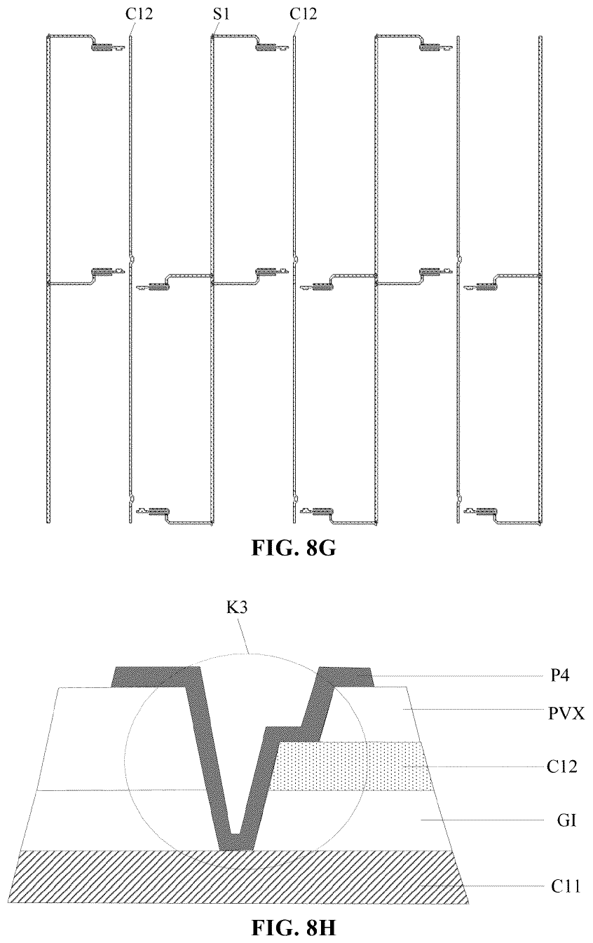

In a possible implementation, referring to FIGS. 8A to 8D, where FIG. 8B may be an enlarged view at dashed box E in FIG. 8A, and FIG. 8C may be an enlarged view at dashed box F in FIG. 8A, the data line layer further includes: a plurality of data lines S1 extending in the second direction, a transistor first electrode S2 electrically connected to a corresponding data line S1, a transistor second electrode S3 spaced apart from the transistor first electrode S2, and a plurality of second common electrode leads C12 extending in the second direction Y. The data lines S1 and the second common electrode leads C12 are alternately arranged in the first direction X. The plurality of pixel electrodes P include first type pixel electrodes P11 and second type pixel electrodes P12 alternately arranged in the first direction X. The first type pixel electrode P11 includes: a first main part P111, a first transfer part P112, and a first connection part P113 connecting the first main part P111 and the first transfer part P112. An orthographic projection of the first transfer part P112 on the substrate 10 has an overlap region with an orthographic projection of the transistor second electrode S3 on the base 10.

The second type pixel electrode P12 includes: a second main part P121, and a second transfer part P122 directly connected to the second main part P121. An orthographic projection of the second transfer part P122 on the substrate 10 has an overlap region with an orthographic projection of the transistor second electrode S3 on the base 10. The second type pixel electrode P12 further includes: a compensation part P123 extending from the second transfer part P122 in the first direction X away from a corresponding data line S1. An orthographic projection of the compensation part P123 on the base 10 is overlapped with an orthographic projection of a corresponding second common electrode lead C12 on the base 10.

In specific implementations, for a dual gate pixel design, some pixel electrodes (e.g., the first type pixel electrode P11) cross the vertical second common electrode lead C12, causing a difference in storage capacitance between pixels, as well as display risks. Specifically, as shown in FIG. 8A, a dual gate and Z-inverted pixel design, and FIG. 8D, a diagram showing a connection relationship in an equivalent circuit corresponding to FIG. 8A, FIG. 8A shows a minimum period of 2*2 pixels (2*6 subpixels), and the case where each pixel is provided with one first common electrode lead C11 is taken as an example for illustration. The case where each pixel is provided with two first common electrode leads C11 is similar, and thus is not repeated herein. Specifically:

Each row of pixels is driven by two gate lines G, while every two columns of subpixels are driven by the same data line S1. Therefore, as shown in FIGS. 8A and 8D, in the 2*2 pixel period, extending in the first direction X are four gate lines G and two first common electrode lead C11 in the same layer as the gate lines G, while extending in the second direction Y are data lines S1 and second common electrode leads C12 alternately arranged. The connection between the first type pixel electrode P11/second type pixel electrode P12 and a thin film transistor TFT varies in length. In FIG. 8D, the pixel electrodes P1 of the subpixels PX1, PX3, PX5, PX8, PX10 and PX12 are second type pixel electrodes P12 which have a short connection design, while the pixel electrodes P1 of the subpixels PX2, PX4, PX6, PX7, PX9 and PX11 are first type of pixel electrodes P11 which have a long connection design across the second common electrode leads C12. The long connection subpixel will add an overlap capacitance with the second common electrode lead C12, and thus is different from the short connection subpixel in the storage capacitance. In other words, a difference in charging rate may be prone to be generated, thereby causing poor display.

In the embodiments of the present disclosure, by providing the compensation part P123 for the second type pixel electrode P12 not crossing the second common electrode lead C12, and providing a capacitance compensation design at the positions indicated by the dashed circles in FIGS. 8C and 8D, the problem of the difference in storage capacitance between pixels can be alleviated.

Specifically, as shown in the figures, an overlap area formed by the orthographic projection of the compensation part P123 on the base 10 and the orthographic projection of the corresponding second common electrode lead C12 on the base 10, is substantially the same as an overlap area formed by the orthographic projection of the first connection part P113 on the base 10 and the orthographic projection of the second common electrode lead C12 on the base 10, so that the storage capacitance is substantially the same throughout the pixels.

Specifically, as shown in FIGS. 8B and 8C, for the first type pixel electrode P11, the first connection part P113 has a length f1 in the second direction Y, and tolerance values of deviation reserved on two sides in the first direction X are f2 and f3, and then for the second type pixel electrode P12, the compensation part P123 has a width g1=f1 in the second direction Y, and tolerance values of deviation reserved on two sides in the first direction X are g2 and g3, respectively. The tolerance values of deviation f2, f3, g2 and g3 should be greater than a maximum alignment deviation between the pixel electrode layer and the data line layer in the actual manufacturing process.

Specifically, referring to FIGS. 8A, 8B and 8C, in an embodiment of the present disclosure, the pixel electrode P may have a slit.

Specifically, referring to FIG. 4, in the non-active area BB, a dummy pixel electrode column may be further disposed on a side of the common electrode connection line C2 facing the active area AA. The dummy pixel electrode column includes a plurality of dummy pixel electrodes DP arranged in the second direction, and transistors corresponding to the dummy pixel electrodes DP are not required to be electrically connected to the dummy pixel electrodes DP.

Specifically, referring to FIGS. 8E, 8F and 8G, where FIG. 8E is a schematic diagram showing a single film layer of a common electrode layer in FIG. 8A, FIG. 8F is a schematic diagram showing a single film layer of a gate line layer in FIG. 8A, and FIG. 8G is a schematic diagram showing a single film layer of a data line layer in FIG. 8A, the array substrate may further include a common electrode layer between the base 10 and the gate line layer. The common electrode layer may include a plurality of common electrode bars C4 extending in the first direction X, at least one of the common electrode bars C4 may include a plurality of common electrode blocks C41 sequentially arranged in the first direction X, and common electrode blocks C41 of the same common electrode bar C4 are electrically connected to the same first common electrode lead C11. Specifically, the first common electrode lead C11 and the common electrode bar C4 may be located in adjacent layers, and the first common electrode lead C11 and the common electrode bar C4 may be electrically connected through direct contact. Specifically, one common electrode bar C4 may correspond to one row of pixel electrodes, and two adjacent common electrode bars C4 may be electrically connected through the second common electrode lead C12. The second common electrode lead C12 may be located in a different layer from the common electrode bar C4, as shown in FIGS. 8B and 8H, where FIG. 8H may be a schematic sectional view taken along dashed line OO′ in FIG. 8B, and specifically, the second common electrode lead C12 may be electrically connected to the first common electrode lead C11 through a third via K3, so that the second common electrode lead C12 is further electrically connected to the common electrode bar C4. Specifically, the pixel electrode layer may further include: a common electrode transfer part P4. The third via K3 may be a half via partially communicated to the first common electrode lead C11 and partially communicated to the second common electrode lead C12, and through the third via K3, a portion of the common electrode transfer part P4 is lapped on the first common electrode lead C11, while another portion of the common electrode transfer part P4 is lapped on the second common electrode lead C12. Specifically, in a subsequent process of forming an alignment film, compared with a deep hole directly communicated to the first common electrode lead C11, the half via design of the third via K3 has a function like a step, which enables a liquid for forming the alignment film to flow into the third via K3 more easily, and reduces the risk of an uneven alignment film at the third via K3. Specifically, referring to FIG. 3A, at an end connected to the connector C21, the first common electrode lead C11 may be electrically connected to the second common electrode connection line C12 through the third via K3.

In a possible implementation, referring to FIG. 1, the non-active area BB further includes a common electrode auxiliary connection line C3 on a side of the common electrode connection line C2 away from the active area AA; and the common electrode auxiliary connection line C3 is electrically conducted with the common electrode connection line C2. In a possible implementation, the common electrode auxiliary connection line C3 and the common electrode connection line C2 may be located in the same layer, and may be both located in the gate line layer. In a possible implementation, a length of the common electrode auxiliary connection line C3 in the second direction Y may be less than a length of the common electrode connection line C2 in the second direction Y; and a maximum width of the common electrode auxiliary connection line C3 in the first direction X may be less than a maximum width of the common electrode connection line C2 in the first direction X. Optionally, a position for the electrical connection between the common electrode auxiliary connection line C3 and the common electrode connection line C2 may be a position in the middle of the common electrode connection line C2 or a position near a central area of the common electrode connection line C2.

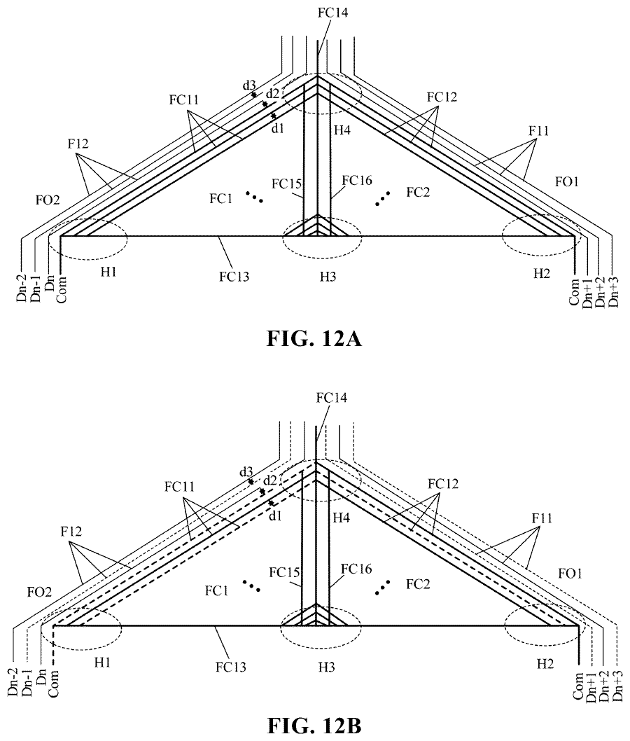

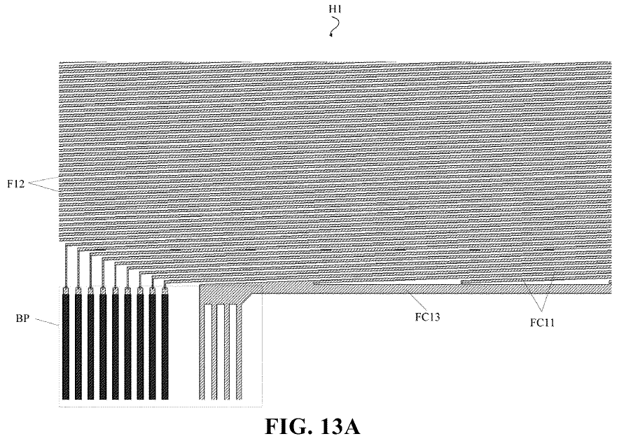

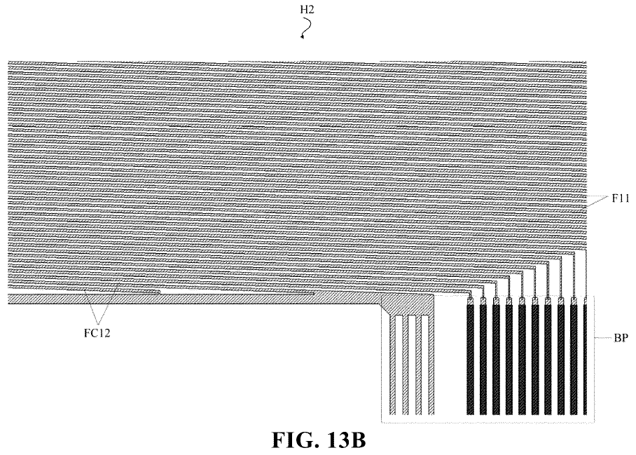

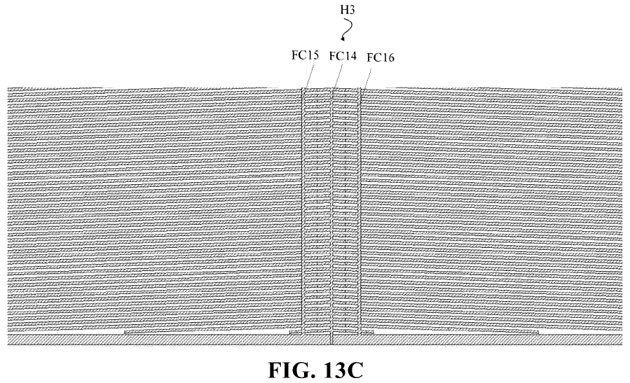

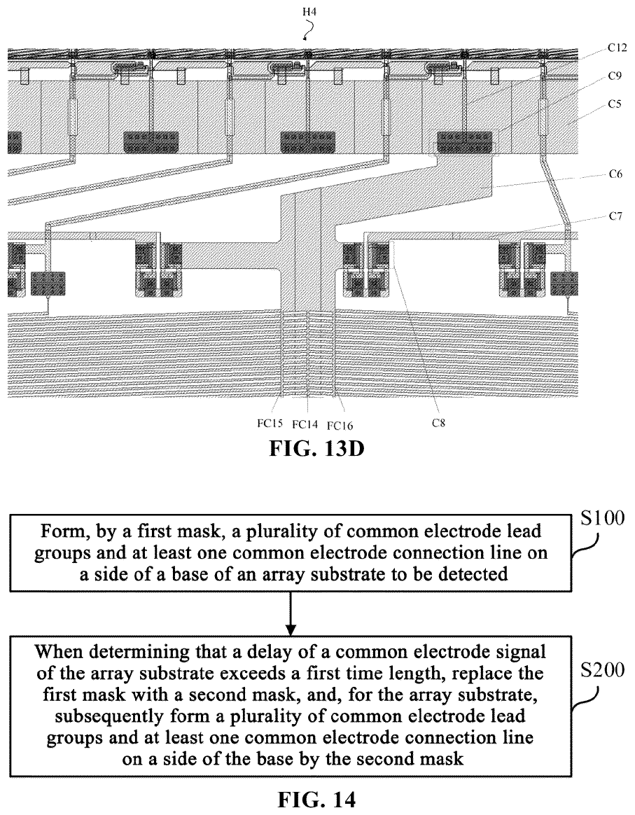

In a possible implementation, referring to FIGS. 11 to 13D, where FIG. 13A may be an enlarged view at dashed box H1 in FIG. 12A, FIG. 13B may be an enlarged view at dashed box H2 in FIG. 12A, FIG. 13C may be an enlarged view at dashed box H3 in FIG. 12A, and FIG. 13D may be an enlarged view at dashed box H4 in FIG. 12A, the non-active area BB is further provided with a plurality of fan-shaped wiring areas FO, and a common signal input area FC is further arranged between adjacent fan-shaped wiring areas FO.

Each fan-shaped wiring area FO includes: a first fan-shaped wiring subarea FO1 and a second fan-shaped wiring subarea FO2. The first fan-shaped wiring subarea FO1 is provided with a plurality of first fan-shaped area wires F11 extending in a third direction J1, and the second fan-shaped wiring subarea FO2 is provided with a plurality of second fan-shaped area wires F12 extending in a fourth direction J2.

The common signal input area FC includes: a first common signal input subarea FC1 and a second common signal input subarea FC2. The first common signal input subarea FC1 is adjacent to the second fan-shaped wiring subarea FO2 in one of the fan-shaped wiring areas FO, and the second common signal input subarea FC2 is adjacent to the first fan-shaped wiring subarea FOI in another one of the fan-shaped wiring areas FO.

The first common signal input subarea FC1 is provided with a plurality of first auxiliary wires FC11 extending in the fourth direction J2, and the second common signal input subarea FC2 is provided with a plurality of second auxiliary wires FC12 extending in the third direction J1.

In the existing art, adjacent fan-shaped wiring areas FO in some display panels may have a long distance therebetween, causing a large wiring span between adjacent fan-shaped area wires in the adjacent fan-shaped wiring areas FO (e.g., between the rightmost second fan-shaped area wire F12 in the left fan-shaped wiring area FO and the leftmost first fan-shaped area wire F11 in the right fan-shaped wiring area FO in FIG. 11), which may cause a great difference in concentration of the etching solution during etching, making the two fan-shaped area wires have non-uniform line widths and an excessive resistance difference, and thus cause a difference in the charging rate level of adjacent pixel columns and screen splitting. In an embodiment of the present disclosure, the first common signal input subarea FC1 is provided with a plurality of first auxiliary wires FC11 extending in the fourth direction J2, and the second common signal input subarea FC2 is provided with a plurality of second auxiliary wires FC12 extending in the third direction J1, which can improve the difference in the line width of the outermost data line (or gate line) in the fan-shaped wiring area FO and other inner data lines (or gate lines), and reduce the risk of poor image quality caused by the difference in resistance of adjacent signal lines in adjacent fan-shaped wiring areas FO.

In a possible implementation, in the case where the wires in the fan-shaped wiring area FO have the same line width, that is, the fan shaped wiring area FO includes first fan-shaped area wires F11 having substantially the same line width, and second fan-shaped area wires F12 having substantially the same line width, and at least part of the first fan-shaped area wires F11 have substantially the same line width as at least part of the second fan-shaped area wires F12,
the common signal input area FC may be provided such that at least part of the first auxiliary wires FC11 have substantially the same line width, at least part of the second auxiliary wires FC12 have substantially the same line width, at least part of the first auxiliary wires FC11 have substantially the same line width as at least part of the second auxiliary wires FC12 and as the at least part of the first fan-shaped area wires F11. Specifically, it may be provided that all the first auxiliary wires FC11 have substantially the same line width, all the second auxiliary wires FC12 have substantially the same line width, all the first auxiliary wires FC11 have substantially the same line width as all the second auxiliary wires FC12 and the first fan-shaped area wires F11. In an embodiment of the present disclosure, all the first auxiliary wires FC11 have substantially the same line width, all the second auxiliary wires FC12 have substantially the same line width, all the first auxiliary wires FC11 have substantially the same line width as all the second auxiliary wires FC12 and the first fan-shaped area wires F11, so that the manufacturing processes of the first auxiliary wires FC11, the second auxiliary wires FC12, the first fan-shaped area wires F11, and the second fan-shaped area wires F12 can be simplified.

In a possible implementation, in the case where the wires in the fan-shaped wiring area FO do not have the same line width, that is, at least part of the first fan-shaped area wires F11 and the second fan-shaped area wires F12 in the fan-shaped wiring area FO have different line widths,
the common signal input area FC may be provided such that at least part of the first auxiliary wires FC11 have substantially the same line width, at least part of the second auxiliary wires FC12 have substantially the same line width, and the first auxiliary wires FC11 and the second auxiliary wires FC12 have substantially the same line width, satisfying Wf1≤Wc1≤Wf2, where Wc1 represents a line width of any first auxiliary wire FC11, Wf1 represents a minimum line width value in the fan-shaped wiring area FO, and Wf2 represents a maximum line width value in the fan-shaped wiring area FO. Specifically, it may be provided that all the first auxiliary wires FC11 have substantially the same line width, all the second auxiliary wires FC12 have substantially the same line width, and the first auxiliary wires FC11 and the second auxiliary wires FC12 have substantially the same line width.

In a possible implementation, in the case where the wires in the fan-shaped wiring area FO do not have the same line width, that is, at least part of the first fan-shaped area wires F11 and the second fan-shaped area wires F12 in the fan-shaped wiring area FO have different line widths,
the common signal input area FC may be provided such that at least part of the first auxiliary wires FC11 have different line widths, satisfying Wf1≤Wc1≤Wf2, where Wc1 represents a line width of any first auxiliary wire FC11, Wf1 represents a minimum line width value in the fan-shaped wiring area FO, and Wf2 represents a maximum line width value in the fan-shaped wiring area FO;
at least part of the second auxiliary wires FC12 may have different line widths, satisfying Wf1≤Wc2≤Wf2, where Wc2 represents a line width of any second auxiliary wire FC12, Wf1 represents a minimum line width value in the fan-shaped wiring area FO, and Wf2 represents a maximum line width value in the fan-shaped wiring area FO.

In a possible implementation, in the case where the wires in the fan-shaped wiring area FO have the same spacing, that is, adjacent first fan-shaped area wires F11 in the fan-shaped wiring area FO have substantially the same line spacing, and adjacent second fan-shaped area wires F12 have substantially the same line spacing;
the common signal input area FC may be provided such that adjacent first auxiliary wires FC11 have substantially the same line spacing, which is substantially the same as the line spacing between the adjacent second fan-shaped area wires F12; and adjacent second auxiliary wires FC12 have substantially the same line spacing, which is substantially the same as the line spacing between the adjacent first fan-shaped area wires F11. In this manner, the manufacturing processes of the first auxiliary wires FC11, the second auxiliary wires FC12, the first fan-shaped area wires F11, and the second fan-shaped area wires F12 can be simplified.

In a possible implementation, a minimum distance between the first auxiliary wires FC11 and the second fan-shaped area wires F12 (e.g., the distance between the leftmost first auxiliary wire FC11 in the common signal input area FC and the rightmost second fan-shaped area wire F12 in the left fan-shaped wiring area FO in FIG. 12A) is substantially the same as the line spacing between the adjacent second fan-shaped area wires F12; and a minimum distance between the second auxiliary wires FC12 and the first fan-shaped area wires F11 (e.g., the distance between the rightmost second auxiliary wire FC12 in the common signal input area FC and the leftmost first fan-shaped area wire F11 in the right fan-shaped wiring area FO in FIG. 12A) is substantially the same as the line spacing between the adjacent first fan-shaped area wires F11.

In a possible implementation, referring to FIGS. 12A or 12B, the common signal input area FC is further provided with at least one third auxiliary wire FC13 extending in the first direction X, and the first auxiliary wires FC11 and the second auxiliary wires FC12 are both intersected with and electrically connected to the third auxiliary wire FC13. In this manner, the metal wire resistance in the common signal input area FC can be reduced, and the common signal transmission capability can be improved. Specifically, the third auxiliary wire FC13 may have a line width greater than or equal to the first auxiliary wire FC11; and the third auxiliary wire FC13 may have a line width greater than or equal to the second auxiliary wire FC12.

In a possible implementation, referring to FIGS. 12A or 12B, the common signal input area FC is further provided with at least one fourth auxiliary wire FC14 extending in the second direction Y, and the first auxiliary wires FC11, the second auxiliary wires FC12 and the third auxiliary wire FC13 are all intersect with and electrically connected to the fourth auxiliary wire FC14. The first common signal input subarea FC1 is further provided with at least one fifth auxiliary wire FC15 extending in the second direction Y, and the first auxiliary wires FC11 and the third auxiliary wire FC13 are both intersected with and electrically connected to the fifth auxiliary wire FC15. The second common signal input subarea FC2 is further provided with at least one sixth auxiliary wire FC16 extending in the second direction Y, and the second auxiliary wires FC12 and the third auxiliary wire FC13 are both intersected with and electrically connected to the sixth auxiliary wire FC16. In this manner, the metal wire resistance in the common signal input area FC can be further reduced, and the common signal transmission capability can be further improved. Specifically, the fourth auxiliary wire FC14 may have a line width greater than or equal to the first auxiliary wire FC11; and the fourth auxiliary wire FC14 may have a line width greater than or equal to the second auxiliary wire FC12. The fifth auxiliary wire FC15 may have a line width greater than or equal to the first auxiliary wire FC11; and the fifth auxiliary wire FC15 may have a line width greater than or equal to the second auxiliary wire FC12. The fifth auxiliary wire FC15 may have a line width greater than or equal to the first auxiliary wire FC11; and the third auxiliary wire FC13 may have a line width greater than or equal to the second auxiliary wire FC12. The sixth auxiliary wire FC16 may have a line width greater than or equal to the first auxiliary wire FC11; and the sixth auxiliary wire FC16 may have a line width greater than or equal to the second auxiliary wire FC12.

In a possible implementation, referring to FIG. 12A, the first fan-shaped area wires F11 and the second fan-shaped area wires F12 are located in the same layer; and the first auxiliary wires FC11 and the second auxiliary wires FC12 are located in the same layer, and in the same layer as the first fan-shaped area wires F11.

In a possible implementation, referring to FIG. 12B, where solid lines represents wires made of a first metal layer, and dashed lines represents wires made of a second metal layer, adjacent first fan-shaped area wires F11 are located in different layers, and different layers of first fan-shaped area wires F11 are alternately arranged; adjacent second fan-shaped area wires F12 are located in different layers, and different layers of second fan-shaped area wires F12 are alternately arranged; adjacent first auxiliary wires FC11 are located in different layers, and different layers of first auxiliary wires FC11 are alternately arranged; and adjacent second auxiliary wires FC12 are located in different layers, and different layers of second auxiliary wires FC12 are alternately arranged. Specifically, for example, all the wires in the fan-shaped wiring area FO and all the wires in the common signal input area FC are disposed in two metal layers, which are a first metal layer and a second metal layer, respectively, where an insulation layer is provided between the first metal layer and the second metal layer. Specifically, for example, in the left fan-shaped wiring area FO, an (n−1)^{th} second fan-shaped area wire F12(Dn−1) is made of the second metal layer, and the adjacent n^{th} second fan-shaped area wire F12 (Dn) is made of the first metal layer; and in the right fan-shaped wiring area FO, an (n+1)^{th} first fan-shaped area wire F11 (i.e., Dn+1 in the right fan-shaped wiring area FO) is made of the second metal layer, an (n+2)^{th} first fan-shaped area wire F11(Dn+2) is made of the first metal layer, so on and so forth. Similarly, in the common signal input area FC, for example, as shown in FIG. 12B from left to right, a first first auxiliary wire FC11 is located in the second metal layer, a second first auxiliary wire FC11 is located in the first metal layer, a third first auxiliary wire FC11 is located in the second metal layer.

Specifically, in the common signal input area FC, the first metal layer is electrically connected to the second metal layer through vias. Specifically, the vias are defined at H1, H2, H3 and H4, respectively, to electrically connect the first metal layer and the second metal layer, where the via design is the same as that of a conventional non-same-layer metal via, which is not described in detail here.

Specifically, the first metal layer and the second metal layer are different layers of metal, and are designed as metals in the same layer as the gate lines, as the data lines, or as other signal lines, which is not limited in the embodiments of the present disclosure.

In a possible implementation, referring to FIG. 12B, one of the first auxiliary wires FC11 and one of the second fan-shaped area wires F12 closest to each other (e.g., the leftmost first auxiliary wire FC11 in the common signal input area FC and the rightmost second fan-shaped area wire F12 in the left fan-shaped wiring area FO in FIG. 12B) are located in different layers; and one of the second auxiliary wires FC12 and one of the first fan-shaped area wires F11 closest to each other (e.g., the rightmost second auxiliary wire FC12 in the common signal input area FC and the leftmost first fan-shaped area wire F11 in the right fan-shaped wiring area FO in FIG. 12B) are located in different layers.

In a possible implementation, at least one of the third auxiliary wire FC13, the fourth auxiliary wire FC14, the fifth auxiliary wire FC15, or the sixth auxiliary wire FC16 includes a plurality of metal layers arranged in a stack, for example, two metal layers arranged in a stack.

In a possible implementation, referring to FIGS. 13A and 13B, the array substrate further includes bonding pads BP electrically connected to the first auxiliary wires FC11 (or the second auxiliary wires FC12), and the bonding pads BP are used for bonding with a bonding pad of a circuit board.

In a possible implementation, referring to FIG. 13D, in the non-active area BB, the array substrate is further provided with a first common signal line C5 extending in the first direction X, a second common signal line C6, an electrostatic discharge ring C7, an electrostatic discharge circuit C8, and a common signal transfer part C9. The second common electrode lead C12 in the active area AA is electrically connected to the second common signal line C6 in the non-active area BB through the common signal transfer part C9 in a transfer manner. The second common signal line C6 is electrically connected to the electrostatic discharge ring C7 through the electrostatic discharge circuit C8 to discharge the generated static electricity.

Based on the same inventive concept, an embodiment of the present disclosure further provides a display panel, including an array substrate according to any embodiment of the present disclosure, and an opposite substrate opposite to the array substrate.

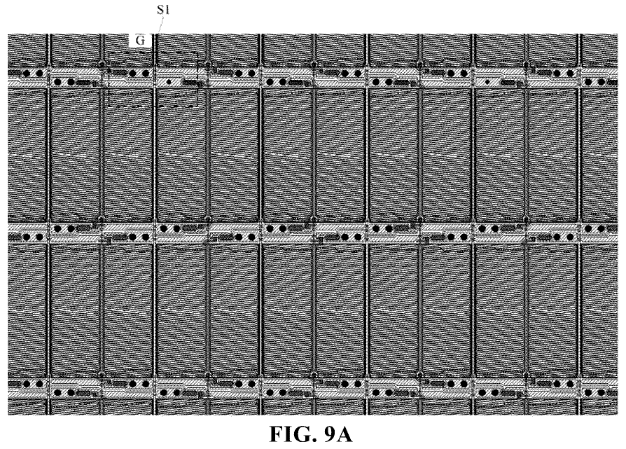

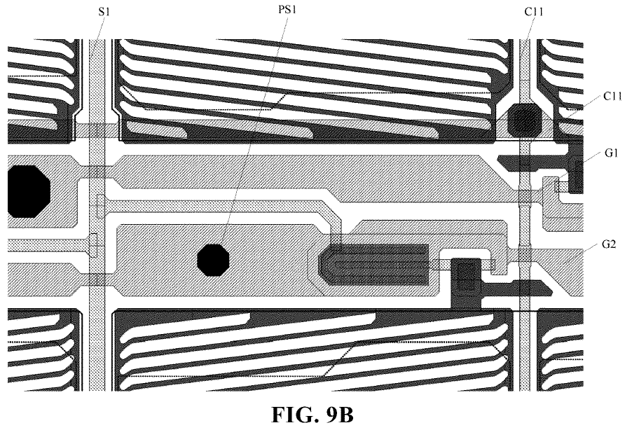

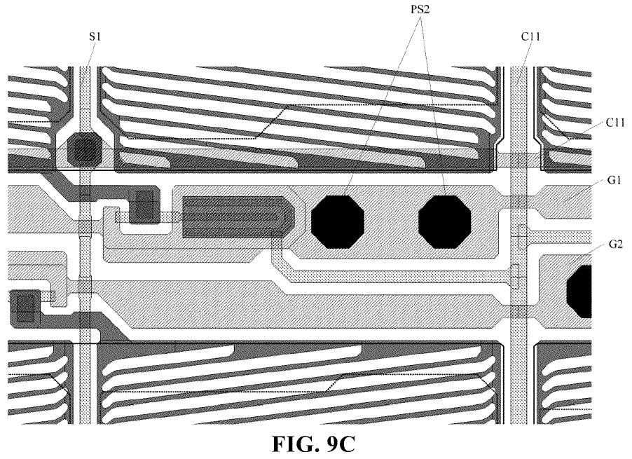

In a possible implementation, referring to FIGS. 9A to 9C, where FIG. 9B is an enlarged view of one first spacer PS1 disposed within dashed box G in FIG. 9A, and FIG. 9C is an enlarged view of two second spacers PS2 disposed within dashed box G in FIG. 9A, the opposite substrate further includes a first spacer PSI and a second spacer PS2. A height of the first spacer PS1 in a direction perpendicular to the base 10 is greater than a height of the second spacer PS2 in the direction perpendicular to the base 10. An orthographic projection of the first gate line G1 on the base 10 covers an orthographic projection of the second spacer PS2 on the base 10, and an orthographic projection of the second gate line G2 on the base 10 covers an orthographic projection of the first spacer PS1 on the base 10.

In the area where at least part of the data lines S1 are located (e.g., the data line S1 at the dashed box G in FIG. 9A), the first spacer PS1 and the second spacer PS2 are respectively located on different sides of the data line S1, and for the first spacer PS1 and the second spacer PS2 on different sides of the same data line S1, the number of first spacers PS1 is less than the number of second spacers PS2.

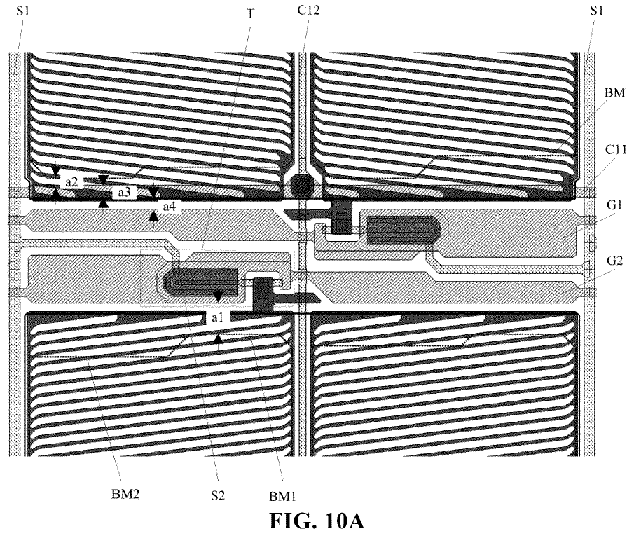

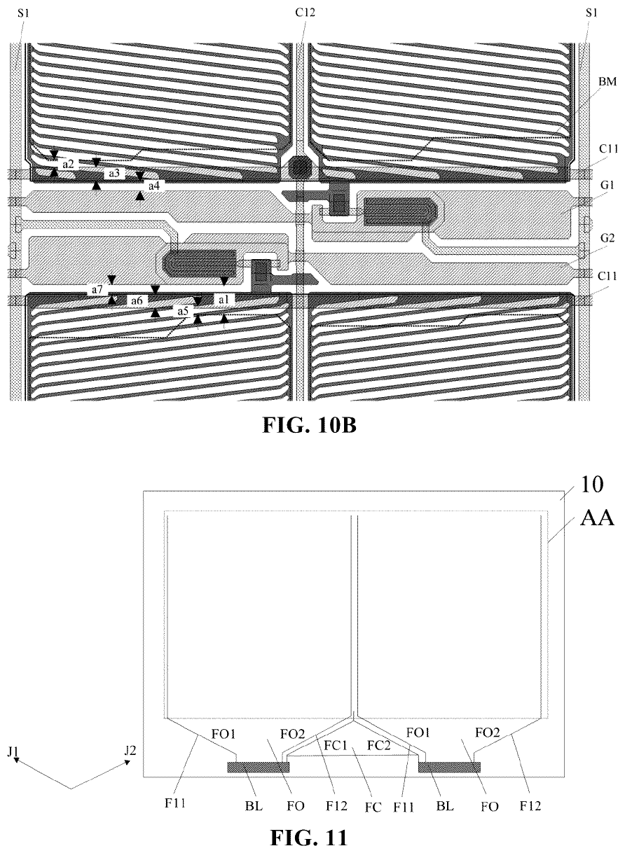

In a possible implementation, referring to FIGS. 10A and 10B, the opposite substrate further includes a black matrix layer on a side of the first spacer PS1 facing away from the opposite substrate. The black matrix layer has a plurality of pixel openings BM, and a minimum distance al between the second gate line G2 and an adjacent pixel opening BM satisfies:
a1=a2+a3+a4, where a2 represents a minimum distance from a first common electrode lead C11 on a side of the first gate line G1 away from the second gate line G2, to a closest pixel opening BM, a3 represents a maximum line width of the first common electrode lead C11 on the side of the first gate line G1 away from the second gate line G2, and a4 represents a minimum distance from the first common electrode lead C11 on the side of the first gate line G1 away from the second gate line G2, to a closest first gate line G1.

In a specific implementation, on a side facing the second gate line G2, the pixel opening BM has a first pixel opening edge BM1 and a second pixel opening edge BM2. The first pixel opening edge BM1 is positioned opposite to a transistor first electrode S2 (the U-shaped opening in FIG. 10A), and the second pixel opening edge BM2 is positioned opposite to the first spacer PS1 or the second spacer PS2 (as shown in FIGS. 9A to 9C). Considering a shift of the first spacer PS1 or the second spacer PS2 under pressure, a distance between the first pixel opening edge BM1 and the second gate line G2 is designed to be greater than a distance between the second pixel opening edge BM2 and the second gate line G2. Specifically, the transistor first electrode S2 may be a source of a transistor T, and the transistor second electrode S2 may be a drain of the transistor T; or, the transistor first electrode S2 may be the drain of the transistor T, and the transistor second electrode S2 may be the source of the transistor T.

In the existing art, where only one first common electrode lead C11 is provided, that is, where the first common electrode lead C11 on the side of the second gate line G2 away from the first gate line G1 is not required, the position is not shielded due to the presence of the black matrix, and therefore, a shorter minimum distance al may be provided between the second gate line G2 and the adjacent pixel opening BM. In the embodiments of the present disclosure, however, since a position is reserved for placing the first common electrode lead C11 on the side of the second gate line G2 away from the first gate line G1, a greater minimum distance al, equal to the sum of a2, a3 and a4, may be provided between the second gate line G2 and the adjacent pixel opening BM, where adjustment is performed at only the first pixel aperture edge BM1, while the second pixel aperture edge BM2 remains unchanged. Therefore, even if a plurality of first common electrode leads C11 are to be provided in the embodiments of the present disclosure, it is still not necessary to change the aperture of the black matrix greatly, thereby avoiding affecting the aperture ratio of the display panel.

Referring to FIG. 14, an embodiment of the present disclosure further provides a method for manufacturing the array substrate according to any embodiment of the present disclosure, which includes the following steps S100 to S200.

At step S100, forming, by a first mask, a plurality of common electrode lead groups and at least one common electrode connection line on a side of a base of an array substrate to be detected. At least one of the common electrode lead groups includes one first common electrode lead extending in a first direction, a connection group is provided at a position of the common electrode connection line opposite to an end of the first common electrode lead, and the connection group includes a plurality of connectors, one of which is electrically connected to the opposite first common electrode lead.

At step S200, when determining that a delay of a common electrode signal of the array substrate exceeds a first time length, replacing the first mask with a second mask, and, for the array substrate, subsequently forming a plurality of common electrode lead groups and at least one common electrode connection line on a side of the base by the second mask. At least one of the common electrode lead groups includes a plurality of first common electrode leads extending in a first direction, a connection group is provided at a position of the common electrode connection line opposite to an end of the first common electrode lead, and the connection group includes a plurality of connectors in one-to-one correspondence and electrical connection with the first common electrode leads.

Specifically, the first time length may be charging time per row of pixel electrodes. In other words, when the delay time of the common electrode signal is substantially the same as the charging time per row of pixel electrodes, it may be considered that the array substrate has severe common electrode signal delay, which may cause poor display. Specifically, if the charging time per row of pixel electrodes H=1/refresh rate/gate line row number, there is a risk of poor display if the delay time of the common electrode signal is 0.5H or more.

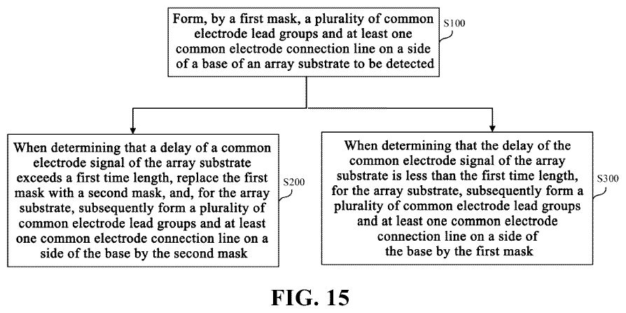

In a possible implementation, referring to FIG. 15, the method further includes the following step S300.

At step S300, when determining that the delay of the common electrode signal of the array substrate is less than the first time length, for the array substrate, subsequently forming a plurality of common electrode lead groups and at least one common electrode connection line on a side of the base by the first mask.

In an embodiment of the present disclosure, within the connection group C20, it is possible that all of the connectors C21 are electrically connected, in one-to-one correspondence, to the opposite first common electrode leads C11, or part of the connectors C21 in the connection group C20 are electrically connected to the opposite first common electrode leads C11. In other words, redundant connectors C21 may be reserved in the connection group C20, and in the manufacturing process of the array substrate, for example, before formally manufacturing the display panel, a film layer of the first common electrode lead C11 may be firstly manufactured by a first mask, where the first mask has a mask pattern of the common electrode lead group C1 including one first common electrode lead C11, and the first common electrode lead C11 is electrically connected to one of the connectors C21. If it is found that the manufactured display panel may have an excessively large Com signal resistance, severe signal delay, or poor display problems related to an insufficient Com signal driving capability, the first mask may be changed and replaced with a second mask, where the second mask has a mask pattern of the common electrode lead group C1 including two first common electrode leads C11, and the two first common electrode leads C11 are electrically connected to the opposite connectors C21, respectively. In this manner, by changing one mask, for example, the design of one first common electrode lead C11 is changed into the design of two first common electrode leads C11, the Com signal resistance is reduced, and the problem of poor display caused by the excessive Com signal resistance in the display panel is solved with the minimum cost.

It should be noted that the array substrate provided in the embodiments of the present disclosure may be suitable for a Twisted Nematic (TN) type liquid crystal display screen, an advanced dimension switch (ADS) type liquid crystal display screen, a high-advanced dimension switch (HADS) type liquid crystal display screen, or an in-plane switch (IPS) type liquid crystal display screen.

Based on the same inventive concept, an embodiment of the present disclosure further provides a display apparatus, which may include a liquid crystal display panel according to any embodiment of the present disclosure. The display apparatus may be: a mobile phone, a tablet, a television, a monitor, a laptop, a digital album, a navigator, a smart watch, a fitness wristband, a personal digital assistant, or any other product or component having a display function. Other essential components of the display device are regarded as present by those skilled in the art, which are not described herein and should not be construed as limiting the present disclosure. In addition, since the display apparatus is used to solve the problem based on a principle similar to that of the display panel, the implementation of the display apparatus may refer to the embodiments of the liquid crystal display panel described above, and repeated descriptions are omitted.

It should be noted that, in the present disclosure, relational terms such as first and second, are used merely for distinguishing one entity or operation from another without necessarily requiring or implying that there is any such actual relationship or order between such entities or operations.

Apparently, various changes and variations may be made to the present disclosure by those skilled in the art without departing from the spirit and scope of the present disclosure. Therefore, if such modifications and variations to the present disclosure are within the scope of the claims of the present disclosure and their equivalents, the present disclosure is also intended to encompass such modifications and variations.

1. An array substrate, having an active area and a non-active area at a periphery of the active area, wherein the array substrate comprises:
a base;
a plurality of common electrode lead groups in the active area and on a side of the base, wherein at least one of the common electrode lead groups comprises at least one first common electrode lead extending in a first direction, and the plurality of common electrode lead groups are arranged in a second direction; and
at least one common electrode connection line, which is in the non-active area, on the same side of the base as the first common electrode lead, and extends in the second direction;
wherein a connection group is provided at a position of the common electrode connection line opposite to an end of at least one of the common electrode lead groups, the connection group comprises a plurality of connectors, and the number of connectors in the connection group is not less than the number of first common electrode leads in the common electrode lead groups.

2. The array substrate according to claim 1, wherein the common electrode lead groups comprise only one first common electrode lead; and
the connection group comprises two connectors, one of which is electrically connected to the first common electrode lead, or
wherein the common electrode lead groups comprise two first common electrode leads; and
the connection group comprises two connectors, one of which is electrically connected to one of the first common electrode leads opposite thereto, and the other of which is electrically connected to the other first common electrode lead.

3. (canceled)

4. The array substrate according to claim 2, wherein the common electrode connection line comprises a body part between two adjacent common electrode lead groups, and a connection part connecting adjacent body parts; wherein a width of the connection part in the first direction is less than a width of the body part in the first direction; and
the two connectors respectively extend in the second direction from an adjacent body part, a gap is provided between the two connectors in the second direction, and the body part, the connection part, and the two connectors form a hollowed-out region opening toward the first common electrode lead.

5. The array substrate according to claim 4, wherein the hollowed-out region has a symmetry axis parallel to the first direction, and the two connectors are symmetrical about the symmetry axis.

6. The array substrate according to claim 4, wherein the array substrate further comprises a gate line layer, and a pixel electrode layer on a side of the gate line layer facing away from the base;
the gate line layer comprises: a plurality of gate lines extending in the first direction, the first common electrode lead, and the common electrode connection line; and
the pixel electrode layer comprises a plurality of pixel electrodes, an orthographic projection of a portion of each pixel electrode facing a corresponding gate line on the base has an overlap region with an orthographic projection of the first common electrode lead on the base.

7. The array substrate according to claim 6, wherein the array substrate further comprises a data line layer;
the array substrate further comprises a gate driver circuit in the non-active area, and gate output signal leads led out from the gate driver circuit and extending in the first direction, wherein the gate output signal leads are in the data line layer; and
the gate output signal leads are conducted with the gate lines in the hollowed-out region through transfer structures.

8. The array substrate according to claim 7, wherein two gate lines are provided between adjacent pixel electrode rows, and two transfer structures corresponding to the two gate lines are symmetrical about the symmetry axis.

9. The array substrate according to claim 7, wherein between an area where the gate driver circuit is located and an area where the common electrode connection line is located, the array substrate is further provided with first output signal wiring areas and second output signal wiring areas; in the second direction, at least part of the first output signal wiring areas and at least part of the second output signal wiring areas are alternately arranged;
each gate output signal lead comprises a first output signal wiring part extending in the first direction, and a second output signal wiring part extending in the second direction; the second output signal wiring part is in a corresponding first output signal wiring area;
each second output signal wiring area is further provided with a plurality of first floating leads extending in the second direction and arranged in the first direction.

10. The array substrate according to claim 9, wherein each first output signal wiring area is further provided with a second floating lead extending in the second direction,
wherein the number of first floating leads in the second output signal wiring area is equal to a sum of the number of second output signal wiring parts and the number of second floating leads in the first output signal wiring area;
a width of each first floating lead in the first direction is substantially the same as a width of the second output signal wiring part in the first direction; a width of the second floating lead in the first direction is substantially the same as the width of the second output signal wiring part in the first direction;
in the first output signal wiring area, a line spacing between the second output signal wiring part and the adjacent second floating lead is substantially equal, and a line spacing between adjacent second output signal wiring parts is substantially equal; and in the second output signal wiring area, a line spacing between adjacent first floating leads is substantially equal.

11. (canceled)

12. The array substrate according to claim 7, wherein the data line layer further comprises: a plurality of data lines extending in the second direction, a transistor first electrode electrically connected to a corresponding data line, a transistor second electrode spaced apart from the transistor first electrode, and a plurality of second common electrode leads extending in the second direction, wherein the data lines and the second common electrode leads are alternately arranged in the first direction;
the plurality of pixel electrodes comprise a first type pixel electrode and a second type pixel electrode alternately arranged in the first direction;
the first type pixel electrode comprises: a first main part, a first transfer part, and a first connection part connecting the first main part and the first transfer part; an orthographic projection of the first transfer part on the base has an overlap region with an orthographic projection of the transistor second electrode on the base;
the second type pixel electrode comprises: a second main part, and a second transfer part directly connected to the second main part, wherein an orthographic projection of the second transfer part on the base has an overlap region with an orthographic projection of the transistor second electrode on the base; and
the second type pixel electrode further comprises: a compensation part extending from the second transfer part in the first direction away from the corresponding data line, wherein an orthographic projection of the compensation part on the base is overlapped with an orthographic projection of a corresponding second common electrode lead on the base.

13. The array substrate according to claim 12, wherein an overlap area formed by the orthographic projection of the compensation part on the base and the orthographic projection of the corresponding second common electrode lead on the base, is substantially the same as an overlap area formed by the orthographic projection of the first connection part on the base and the orthographic projection of the second common electrode lead on the base.

14. (canceled)

15. The array substrate according to claim 1, wherein the non-active area is further provided with a plurality of fan-shaped wiring areas, and a common signal input area is further arranged between adjacent fan-shaped wiring areas;
the fan-shaped wiring area comprises: a first fan-shaped wiring subarea and a second fan-shaped wiring subarea, wherein the first fan-shaped wiring subarea is provided with a plurality of first fan-shaped area wires extending in a third direction, and the second fan-shaped wiring subarea is provided with a plurality of second fan-shaped area wires extending in a fourth direction; and
the common signal input area comprises: a first common signal input subarea and a second common signal input subarea, wherein the first common signal input subarea is adjacent to the second fan-shaped wiring subarea in one of the fan-shaped wiring areas, and the second common signal input subarea is adjacent to the first fan-shaped wiring subarea in another one of the fan-shaped wiring areas; and
the first common signal input subarea is provided with a plurality of first auxiliary wires extending in the fourth direction, and the second common signal input subarea is provided with a plurality of second auxiliary wires extending in the third direction.

16. The array substrate according to claim 15, wherein the fan-shaped wiring area comprises first fan-shaped area wires having substantially the same line width, and second fan-shaped area wires having substantially the same line width, and at least part of the first fan-shaped area wires have substantially the same line width as at least part of the second fan-shaped area wires; and
at least part of the first auxiliary wires have substantially the same line width, at least part of the second auxiliary wires have substantially the same line width, and at least part of the first auxiliary wires have substantially the same line width as at least part of the second auxiliary wires and as the at least part of the first fan-shaped area wires, or
wherein for the first fan-shaped area wires and the second fan-shaped area wires in the fan-shaped wiring area, at least part of the wires have different line widths; and
all the first auxiliary wires have substantially the same line width, and all the second auxiliary wires have substantially the same line width, satisfying Wf1≤Wc1≤Wf2, where Wc1 represents a line width of any first auxiliary wire, Wf1 represents a minimum line width value in the fan-shaped wiring area, and Wf2 represents a maximum line width value in the fan-shaped wiring area; or
wherein for the first fan-shaped area wires and the second fan-shaped area wires in the fan-shaped wiring area, at least part of the wires have different line widths;
at least part of the first auxiliary wires have different line widths, satisfying Wf1≤Wc1≤Wf2, where Wc1 represents a line width of any second auxiliary wire, Wf1 represents a minimum line width value in the fan-shaped wiring area, and Wf2 represents a maximum line width value in the fan-shaped wiring area; and
at least part of the second auxiliary wires have different line widths, satisfying Wf1≤Wc2≤Wf2, where Wc2 represents a line width of any second auxiliary wire, Wf1 represents a minimum line width value in the fan-shaped wiring area, and Wf2 represents a maximum line width value in the fan-shaped wiring area.

17-18. (canceled)

19. The array substrate according to claim 15, wherein in the fan-shaped wiring area, adjacent first fan-shaped area wires have substantially the same line spacing therebetween, and adjacent second fan-shaped area wires have substantially the same line spacing therebetween;
adjacent first auxiliary wires have substantially the same line spacing, which is substantially the same as the line spacing between the adjacent second fan-shaped area wires; and adjacent second auxiliary wires have substantially the same line spacing, which is substantially the same as the line spacing between the adjacent first fan-shaped area wires.

20. The array substrate according to claim 19, wherein a minimum distance between the first auxiliary wires and the second fan-shaped area wires is substantially the same as the line spacing between the adjacent second fan-shaped area wires; and
a minimum distance between the second auxiliary wires and the first fan-shaped area wires is substantially the same as the line spacing between the adjacent first fan-shaped area wires.

21. The array substrate according to claim 15, wherein the common signal input area is further provided with at least one third auxiliary wire extending in the first direction, and the first auxiliary wires and the second auxiliary wires are both intersected with and electrically connected to the third auxiliary wire.

22. The array substrate according to claim 21, wherein the common signal input area is further provided with at least one fourth auxiliary wire extending in the second direction, and the first auxiliary wires, the second auxiliary wires and the third auxiliary wire are all intersect with and electrically connected to the fourth auxiliary wire;
the first common signal input subarea is further provided with at least one fifth auxiliary wire extending in the second direction, and the first auxiliary wires and the third auxiliary wire are both intersected with and electrically connected to the fifth auxiliary wire; and
the second common signal input subarea is further provided with at least one sixth auxiliary wire extending in the second direction, and the second auxiliary wires and the third auxiliary wire are both intersected with and electrically connected to the sixth auxiliary wire.

23. The array substrate according to claim 15, wherein the first fan-shaped area wires and the second fan-shaped area wires are in the same layer; and
the first auxiliary wires and the second auxiliary wires are in the same layer, and in the same layer as the first fan-shaped area wires, or
wherein adjacent first fan-shaped area wires are in different layers, different layers of the first fan-shaped area wires are alternatively arranged, adjacent second fan-shaped area wires are different layers, and different layers of second fan-shaped area wires are alternately arranged;
adjacent first auxiliary wires are in different layers, and different layers of first auxiliary wires are alternately arranged; and adjacent second auxiliary wires are in different layers; and different layers of second auxiliary wires are alternately arranged;
one of the first auxiliary wires and one of the second fan-shaped area wires closest to each other are in different layers; and
one of the second auxiliary wires and one of the first fan-shaped area wires closest to each other are in different layers.

24-27. (canceled)

28. A display panel, comprising the array substrate according to claim 1, and an opposite substrate opposite to the array substrate, wherein two gate lines, a first gate line and a second gate line, are provided between adjacent pixel electrode rows;
the opposite substrate further comprises a first spacer and a second spacer on a side of a black matrix layer facing the array substrate, wherein a height of the first spacer in a direction perpendicular to the base is greater than a height of the second spacer in the direction perpendicular to the base; an orthographic projection of the first gate line on the base covers an orthographic projection of the second spacer on the base, and an orthographic projection of the second gate line on the base covers an orthographic projection of the first spacer on the base; and
in an area where at least part of data lines are located, the first spacer and the second spacer are respectively on different sides of the data line, and for the first spacers and the second spacers on different sides of the same data line, the number of the first spacers is less than the number of the second spacers.

29. The display panel according to claim 28, wherein the opposite substrate has the black matrix layer having a plurality of pixel openings, and a minimum distance al between the second gate line and an adjacent pixel opening satisfies:
a1=a2+a3+a4, where a2 represents a minimum distance from a first common electrode lead on a side of the first gate line away from the second gate line, to a closest pixel opening, a3 represents a maximum line width of the first common electrode lead on the side of the first gate line away from the second gate line, and a4 represents a minimum distance from the first common electrode lead on the side of the first gate line away from the second gate line, to a closest first gate line.

30-31. (canceled)
